(19) United States
(12) Patent Application Publication
(10) Pub. No.: US 2014/0176179 A1
(43) Pub. Date: Jun. 26, 2014

(54) PSEUDO-SOLAR RADIATION DEVICE

(71) Applicants: Kohji Minami, Osaka-shi (JP); Masaru Ogawa, Osaka-shi (JP)

(72) Inventors: Kohji Minami, Osaka-shi (JP); Masaru Ogawa, Osaka-shi (JP)

(73) Assignee: SHARP KABUSHIKI KAISHA, Osaka-shi, Osaka (JP)

(21) Appl. No.: 14/237,684

(22) PCT Filed: Apr. 2, 2012
(86) PCT No.: PCT/JP2012/058793

§ 371 Date: Feb. 7, 2014

(30) Foreign Application Priority Data
Oct. 31, 2011 (JP) 2011-239813

(51) Int. Cl. F21V 9/02; G01R 31/26

(52) U.S. Cl. CPC F21V 9/02; G01R 31/2605
USPC 324/761.01; 362/2

(57) ABSTRACT

A simulated sunlight irradiation apparatus of the present invention (100a) includes: a light guide plate (5) having an irradiation surface and a counter surface opposite to the irradiation surface; and a light absorbing member (8) which is provided on at least one of an irradiation surface side and a counter surface side of the light guide plate (5) and absorbs light in a predetermined wavelength region.

### TECHNICAL FIELD

The present invention relates to a simulated sunlight irradiation apparatus, specifically a simulated sunlight irradiation apparatus which suppresses re-application, to an irradiation target such as a solar cell, of light reflected from the irradiation target.

### BACKGROUND ART

The importance of a solar cell has been recognized as a clean energy source, and a demand for such solar cell is increasing. The solar cell is used in various technical fields ranging from power sources for large electric equipments to small power sources for precision electronic devices.

If the solar cell is to be widely used in various technical fields, then characteristics of the solar cell, particularly, an output characteristic of the solar cell should be precisely measured. Otherwise, various inconveniences in use of the solar cell may possibly occur. Therefore, there is a demand for development of a technique which is available to tests, measurements and experiments of the solar cell and which can irradiate a large area with high-accuracy simulated sunlight.

Major requirements which the simulated sunlight should meet are (i) to make an emission spectrum of the simulated sunlight similar to that of the standard sunlight (set by the Japanese Industrial Standards: JIS C8941) and (ii) to make an irradiance of the simulated sunlight substantially equal to that of the standard sunlight.

In view of such requirements, a simulated sunlight irradiation apparatus has been developed as a device for performing irradiation with simulated sunlight that meets such requirements. Generally, the simulated sunlight irradiation apparatus is used for measuring an output characteristic of the solar cell, such as an amount of power generated by the solar cell, by irradiating a light receiving surface of the solar cell with artificial light (simulated sunlight) whose irradiance is uniform.

In connection with such simulated sunlight irradiation apparatus, for example, Patent Literature 1 discloses a technique for adjusting uneven irradiance of a simulated sunlight irradiation apparatus. Specifically, Patent Literature 1 discloses a simulated sunlight irradiation apparatus (solar simulator) which includes a halogen lamp and a xenon lamp and whose uneven irradiance is adjusted by causing light emitted from the lamps to be reflected by respective reflecting plates, which are provided for the respective lamps, toward a solar cell. The simulated sunlight irradiation apparatus further includes optical filters for forming a spectrum of simulated sunlight between the solar cell and the reflecting plates. This allows the simulated sunlight irradiation apparatus to irradiate the solar cell with simulated sunlight whose uneven irradiance has been adjusted.

### CITATION LIST

### Patent Literature

Patent Literature 1
Japanese Patent Application Publication, Tokukai, No. 2002-48704 A (Publication Date: Feb. 15, 2002)

### SUMMARY OF INVENTION

### Technical Problem

However, such conventional technique as described above does not allow precise measurement of an output characteristic of a solar cell, due to an influence of reflected light which is generated when simulated sunlight is reflected from the solar cell.

Specifically, when the solar cell is irradiated with simulated sunlight, part of the simulated sunlight is reflected, without being received by the solar cell, from a surface of the solar cell and the like toward the simulated sunlight irradiation apparatus (hereinafter referred to as reflected light).

In a case where the reflected light is mixed into simulated sunlight for measuring an output characteristic of the solar cell which simulated sunlight is emitted from the simulated sunlight irradiation apparatus, and then light thus mixed is applied to the solar cell, the solar cell receives the simulated sunlight including the reflected light. Accordingly, an amount of power generated by the solar cell is increased because of the reflected light mixed in the simulated light. That is, an output characteristic value which is beyond an actual output characteristic of the solar cell is obtained, and thus there was an error in measured output characteristic of the solar cell.

Such decrease in measurement precision affected by reflected light is caused more by an influence of light in an infrared region than by an influence of light in an ultraviolet region, out of light contained in the reflected light. This is because the solar cell has a higher sensitivity to light in the infrared region than to light in the ultraviolet region. In a case where a Si solar cell is used, the decrease in measurement precision affected by reflected light in the infrared region is even greater.

Further, in the case of the simulated sunlight irradiation apparatus disclosed in Patent Literature 1, light is reflected also from the optical filter for the halogen lamp, the optical filter for the xenon lamp, an acrylic plate, and the like which are located closer to the solar cell than the respective lamps are. As such, the decrease in measurement precision affected by reflected light becomes significant. However, Patent Literature 1 mentions no technical idea for solving this.

The present invention is accomplished in view of the problem. An object of the present invention is to provide a simulated sunlight irradiation apparatus which suppresses re-application, to an irradiation target, of light reflected from the irradiation target.

### Solution to Problem

In order to attain the object, a simulated sunlight irradiation apparatus of the present invention is a simulated sunlight irradiation apparatus including: a light source emitting light; a spectrum adjusting member adjusting a spectrum of the light emitted from the light source; a light guide plate which the light whose spectrum has been adjusted by the spectrum adjusting member enters and in which the light is guided, the light guide plate having an irradiation surface and a counter surface opposite to the irradiation surface; a light extracting member causing the light which has entered the light guide plate to be extracted through the irradiation surface toward an irradiation target; and a light absorbing member absorbing light in a predetermined wavelength region, the light absorbing member being provided on at least one of an irradiation surface side and a counter surface side of the light guide plate.

With the above arrangement, light from the light source is adjusted by the spectrum adjusting member so as to have a desired spectral distribution, and then enters the light guide plate as simulated sunlight. Then, the light which has entered the light guide plate is emitted, by means of the light extracting member, through the irradiation surface of the light guide plate toward the irradiation target.

Note, here, that in a conventional case where a solar cell, which is an irradiation target, is irradiated with simulated sunlight by use of a simulated sunlight irradiation apparatus in order to measure an output characteristic of the solar cell, simulated sunlight (hereinafter referred to as reflected light) reflected from the solar cell is re-applied to the solar cell, so that an error is caused in measured output characteristic of the solar cell.

In view of this, in the above arrangement, the light absorbing member absorbing light in the predetermined wavelength region is provided on at least one of the irradiation surface side and the counter surface side of the light guide plate. As such, by controlling, in accordance with the wavelength region of the reflected light, a wavelength region of light absorbed by the light absorbing member, the reflected light can be absorbed by use of the light absorbing member.

Therefore, the above arrangement makes it possible to provide a simulated sunlight irradiation apparatus which suppresses re-application, to an irradiation target, of light reflected from the irradiation target. This makes it possible to reduce a measurement error as described above of an output characteristic of the solar cell.

Further, in order to attain the object, a simulated sunlight irradiation apparatus of the present invention is a simulated sunlight irradiation apparatus which irradiates a solar cell with simulated sunlight in order to measure an output characteristic of the solar cell, including: a light source emitting light; a spectrum adjusting member adjusting a spectrum of the light emitted from the light source; a light guide plate which the light whose spectrum has been adjusted by the spectrum adjusting member enters and in which the light is guided, the light guide plate having an irradiation surface and a counter surface opposite to the irradiation surface; a light extracting member causing the light which has entered the light guide plate to be extracted through the irradiation surface toward an irradiation target; and a light absorbing member capable of absorbing light that is in a predetermined wavelength region and contained in reflected light which is simulated sunlight reflected from the solar cell, the light absorbing member being provided on at least one of an irradiation surface side and a counter surface side of the light guide plate.

The above arrangement makes it possible to provide a simulated sunlight irradiation apparatus which suppresses re-application, to a solar cell, of light reflected from the solar cell. This makes it possible to reduce a measurement error as described above of an output characteristic of the solar cell.

### Advantageous Effects of Invention

As described above, a simulated sunlight irradiation apparatus of the present invention is a simulated sunlight irradiation apparatus including: a light source emitting light; a spectrum adjusting member adjusting a spectrum of the light emitted from the light source; a light guide plate which the light whose spectrum has been adjusted by the spectrum adjusting member enters, the light guide plate having an irradiation surface and a counter surface opposite to the irradiation surface; a light extracting section causing the light which has entered the light guide plate to be extracted through the irradiation surface toward an irradiation target; and a light absorbing member absorbing light in a predetermined wavelength region, the light absorbing member being provided on at least one of an irradiation surface side and a counter surface side of the light guide plate.

Therefore, the present invention makes it possible to provide a simulated sunlight irradiation apparatus which suppresses re-application, to an irradiation target, of light reflected from the irradiation target. This makes it possible to reduce a measurement error as described above of an output characteristic of a solar cell.

### BRIEF DESCRIPTION OF DRAWINGS

FIG. 1 is a side view illustrating a substantial arrangement of a simulated sunlight irradiation apparatus in accordance with Embodiment 1.

FIG. 2 is a top view illustrating part of a light introducing section illustrated in FIG. 1.

FIG. 3 is a schematic view illustrating an optical path of simulated sunlight in the simulated sunlight irradiation apparatus illustrated in FIG. 1.

FIG. 4 is a side view illustrating a first modified example of the simulated sunlight irradiation apparatus illustrated in FIG. 1.

FIG. 5 is an enlarged view illustrating a portion within a broken line illustrated in FIG. 4.

FIG. 6 is a side view illustrating a second modified example of the simulated sunlight irradiation apparatus illustrated in FIG. 1.

FIG. 7 is a side view illustrating a third modified example of the simulated sunlight irradiation apparatus illustrated in FIG. 1.

FIG. 8 is a schematic view illustrating an optical path of simulated sunlight in the simulated sunlight irradiation apparatus illustrated in FIG. 7.

FIG. 9 is a side view illustrating a fourth modified example of the simulated sunlight irradiation apparatus illustrated in FIG. 1.

FIG. 10 is a side view illustrating a substantial arrangement of a simulated sunlight irradiation apparatus in accordance with Embodiment 2.

FIG. 11 is a side view illustrating a first modified example of the simulated sunlight irradiation apparatus illustrated in FIG. 10.

FIG. 12 is a side view illustrating a second modified example of the simulated sunlight irradiation apparatus illustrated in FIG. 10.

(a) through (c) of FIG. 13 are graphs showing results of simulations in Example.

### DESCRIPTION OF EMBODIMENTS

### Embodiment 1

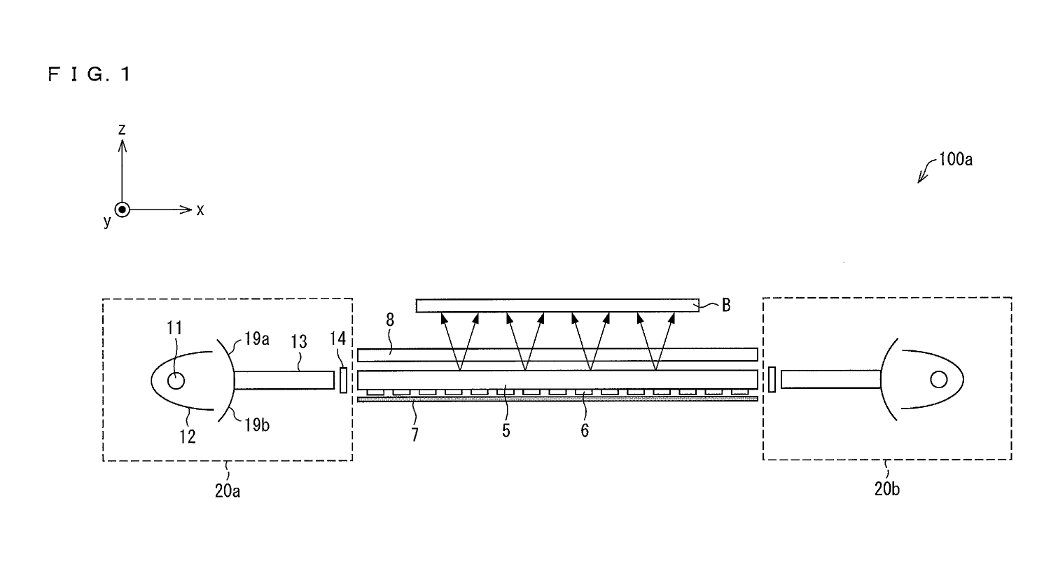

The following description will discuss, with reference to FIGS. 1 through 9, an embodiment of a simulated sunlight irradiation apparatus of the present invention. The description of the present embodiment will deal with a case where a solar cell panel or a solar cell module (hereinafter referred to as solar cell), each of which is an irradiation target, is irradiated with simulated sunlight by use of a simulated sunlight irradiation apparatus of the present invention.

<Arrangement of Simulated Sunlight Irradiation Apparatus>

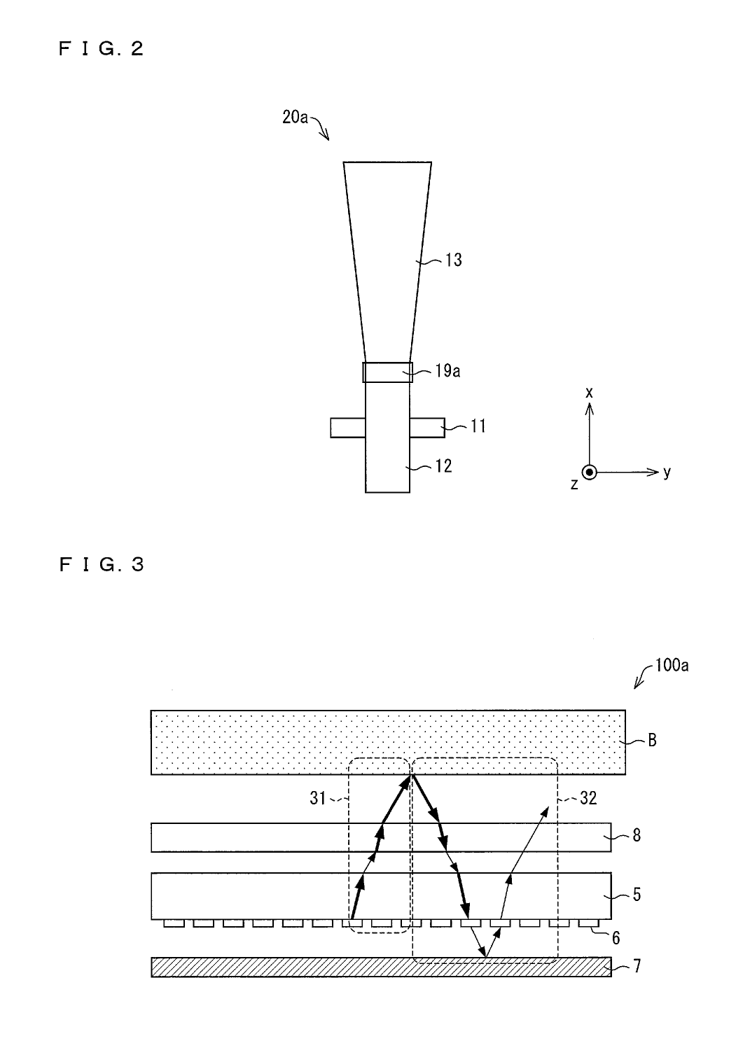

First, an arrangement of a simulated sunlight irradiation apparatus 100a in accordance with the present embodiment is described with reference to FIGS. 1 and 2. the simulated sunlight irradiation apparatus 100a in accordance with the present embodiment irradiates a solar cell B with simulated sunlight in order to measure an output characteristic of the solar cell B. Note that the simulated sunlight is a kind of artificial light and has an emission spectrum extremely similar to that of natural light (sunlight).

FIG. 1 is a side view illustrating a substantial arrangement of the simulated sunlight irradiation apparatus 100a in accordance with the present embodiment, and FIG. 2 is a top view illustrating part of a light introducing section 20a illustrated in FIG. 1. Note that FIG. 1 omits a holding member for holding the solar cell B, and the like.

As illustrated in FIG. 1, the simulated sunlight irradiation apparatus 100a includes the light introducing section 20a, a light introducing section 20b, a light guide plate 5, a light extracting section (light extracting member) 6, a reflecting plate (reflecting member) 7, and a light absorbing member 8. The simulated sunlight irradiation apparatus 100a emits simulated sunlight (indicated by arrows in FIG. 1) from a top surface (irradiation surface) of the light guide plate 5 toward the solar cell B.

The following discusses in detail members constituting the simulated sunlight irradiation apparatus 100a. Note that in the following description, an irradiation surface side of the light guide plate 5 is referred to as an upper side and a bottom surface (counter surface) side opposite to the irradiation surface side of the light guide plate 5 is referred to as a lower side.

(Light Introducing Section)

The light introducing sections 20a and 20b each generate simulated sunlight by adjusting a spectrum of light emitted from a light source, and emits the simulated sunlight thus generated to the light guide plate 5. In the simulated sunlight irradiation apparatus 100a, the light introducing sections 20a and 20b are provided on respective both end surfaces of the light guide plate 5. This makes it possible to cause simulated sunlight with a higher intensity (irradiance) to be emitted through the irradiation surface of the light guide plate 5.

However, note that the light introducing sections 20a and 20b are not necessarily provided to the respective end surfaces of the light guide plate 5. Either one of the light introducing sections 20a and 20b may be provided to only one end surface of the light guide plate 5. In other words, the simulated sunlight irradiation apparatus 100a does not need to include the light introducing section 20b. In this case, by changing a shape, a positional configuration, or the like of a light extracting section 6 (described later), uneven irradiance of simulated sunlight can be adjusted.

Note that the light introducing sections 20a and 20b have an identical arrangement. Therefore, the following discusses only an arrangement of the light introducing section 20a.

As illustrated in FIGS. 1 and 2, the light introducing section 20a includes a xenon lamp 11, an ellipse mirror 12, reflecting members 19a and 19b, a taper coupler 13, and an optical filter (spectrum adjusting member) 14.

The xenon lamp 11 emits light having a spectral distribution required for generation of the simulated sunlight. Note that, although the simulated sunlight irradiation apparatus 100a employs the xenon lamp 11 as the light source, the light source is not limited to any specific type provided that it is capable of emitting light having the spectral distribution required for the generation of the simulated sunlight. For example, a halogen lamp or the like can be employed in place of the xenon lamp 11.

The ellipse mirror 12 collects light emitted from the xenon lamp 11, and reflects the thus collected light toward the taper coupler 13. The ellipse mirror 12 is provided so that the xenon lamp 11 is surrounded by the ellipse mirror 12 in all directions except a direction in which light is emitted toward the taper coupler 13. In this arrangement, light that does not travel toward the taper coupler 13 among light emitted from the xenon lamp 11 can be caused to be reflected from the ellipse mirror 12 toward the taper coupler 13.

This allows light emitted directly from the xenon lamp 11 and light reflected from the ellipse mirror 12 to enter an incident surface of the taper coupler 13. Therefore, the light emitted from the xenon lamp 11 can be more efficiently used.

The reflecting members 19a and 19b are provided so as to enclose the incident surface of the taper coupler 13, and light that does not enter the incident surface of the taper coupler 13, out of the light directly emitted from the xenon lamp 11 and the light reflected from the ellipse mirror 12, is reflected by the reflecting members 19a and 19b toward the ellipse mirror 12. This allows the light that does not enter the incident surface of the taper coupler 13 to be guided toward the ellipse mirror 12 again. Therefore, the light emitted from the xenon lamp 11 can be further more efficiently used.

The taper coupler 13 is an optical element provided in the light introducing section 20a. The taper coupler 13 is provided between the xenon lamp 11 and the optical filter 14. One end of the taper coupler 13 is provided so as to be close to the xenon lamp 11, and the other end is provided so as to be close to the optical filter 14. Two opposed surfaces of the taper coupler 13 in a z axis direction each has a taper shape, and the taper coupler 13 is capable of causing incident light to be totally reflected inside the taper couple 13 to thereby give a predetermined directivity to the light emitted from the xenon lamp 11. Note that control of directivity carried out in the light introducing sections 20a and 20b will be described later.

The optical filter 14 is provided so that a spectrum of the light emitted from the xenon lamp 11 approximates the spectrum of the standard sunlight. The optical filter 14 is an optical element which adjusts a spectrum (controls a transmittance) of light emitted from the taper coupler 13, and is usually called an air mass filter (spectral adjusting filter).

Specifically, the optical filter 14 is provided so as to be close to an exit surface of the taper coupler 13 for the xenon lamp 11, and adjusts a spectral distribution of the light that exits from the taper coupler 13. This allows the light whose spectral is adjusted by the optical filter 14 to enter the light guide plate 5 as simulated sunlight.

(Light Guide Plate)

The light guide plate 5 is provided between the light introducing sections 20a and 20b which face each other. The light guide plate 5 emits, through the irradiation surface of the light guide plate 5, simulated sunlight having entered the light guide plate from the light introducing sections 20a and 20b via the both end surfaces of the light guide plate 5. On the bottom surface of the light guide plate 5, the light extracting section 6 is provided so that the simulated sunlight is emitted through the irradiation surface toward the solar cell B.

(Light Extracting Section)

The light extracting section 6 is formed on the bottom surface of the light guide plate 5. The light extracting section 6 causes the simulated sunlight emitted from the light introducing sections 20a and 20b to be extracted through the irradiation surface of the light guide plate 5. More specifically, the simulated sunlight having entered the light guide plate 5 from the light introducing sections 20a and 20b propagates inside the light guide plate 5. At this time, the simulated sunlight hitting on the light extracting section 6 is emitted through the irradiation surface of the light guide plate 5. This allows the simulated sunlight to be emitted, with a uniform distribution, through a large irradiation surface.

Note that the light extracting section 6 can be made of, for example, a scatterer. This makes it possible to scatter the simulated sunlight inside the light guide plate 5 to thereby cause such part of the simulated sunlight which is out of a total reflection condition to be extracted outside through the irradiation surface of the light guide plate 5 and emitted toward the solar cell B. Further, by changing a pattern of the scatterer, unevenness in irradiance of the simulated sunlight can also be adjusted.

The light extracting section 6 can be formed by printing, metal molding, or the like. In this case, a pattern, such as shape, size, pitch, or interval, of dots formed on the bottom surface of the light guide plate 5 is appropriately set by taking account of a size of the solar cell B or the like so that an entire light receiving surface of the solar cell B is uniformly irradiated with the simulated sunlight.

(Reflecting Plate)

The reflecting plate 7 is provided on the bottom surface side of the light guide plate 5, and reflects, toward the top surface of the light guide plate 5, simulated sunlight and the like having been emitted from the bottom surface of the light guide plate 5. Provision of the reflecting plate 7 allows more efficient use of light in the simulated sunlight irradiation apparatus 100a, since the simulated sunlight emitted from the bottom surface of the light guide plate 5 is reflected by the reflecting plate 7 toward the top surface of the light guide plate 5, i.e., toward the solar cell B. Note that the reflecting plate 7 is not an essential arrangement for the simulated sunlight irradiation apparatus 100a, and can be omitted.

(Light Absorbing Member)

The light absorbing member 8 absorbs light in a predetermined wavelength region. The light absorbing member 8 is provided for the purpose of absorbing simulated sunlight (hereinafter referred to as reflected light) that is not received but reflected by the solar cell B among simulated sunlight with which the solar cell B is irradiated.

It should be noted here that, conventionally, in a case where the solar cell B is irradiated with simulated sunlight by use of a simulated sunlight irradiation apparatus in order to measure an output characteristic of the solar cell B, accurate measurement of the output characteristic of the solar cell B is not possible due to an influence of reflected light from the solar cell B. That is, the reflected light is reflected from a surface of a light guide plate 5 and from a reflecting plate 7, and then re-applied to the solar cell B together with simulated sunlight (hereinafter referred to as measurement light) for measuring the output characteristic of the solar cell B which simulated sunlight is emitted from the light guide plate 5. This results in an error in measured output characteristic of the solar cell B.

In view of this, the simulated sunlight irradiation apparatus 100a includes the light absorbing member 8 which is provided between the light guide plate 5 and the solar cell B and absorbs light in the predetermined wavelength region. By absorbing part of the reflected light by use of the light absorbing member 8, the influence of the reflected light is reduced.

Examples of the light absorbing member 8 can encompass (i) an optical filter made up of a multilayer film including an absorbent material, (ii) an ND filter having a low attenuation rate, and (iii) light-absorbing glass such as colored glass. It is particularly preferable that the light absorbing member 8 be soda glass. This makes it possible to provide a suitable light absorbing member 8 which is capable of effectively reducing the influence of the reflected light and has a simple arrangement.

Soda glass has a property of absorbing light in a wavelength region ranging from a red region to an infrared region. That is, soda glass has a property of absorbing light in a wavelength region of 650 nm to 1100 nm among light in a wavelength region (for example, 350 nm to 1100 nm under Japanese Industrial Standards (JIS)) required by the simulated sunlight irradiation apparatus 100a in order to irradiate the solar cell B with light.

For example, soda glass having a thickness of 3 mm absorbs approximately 10% of light in a wavelength region of not less than 650 nm but not more than 1100 nm. An influence of light in the infrared region (mainly in a range of 850 nm to 1100 nm) among the reflected light is particularly great. In particular, a Si solar cell B, which has a high photoelectric conversion efficiency with respect to light in the infrared region, and another solar cell B are respectively irradiated with the same intensity of reflected light, the Si solar cell B is affected more than the another solar cell B by the reflected light mixed in the simulated sunlight.

In view of this, by providing soda glass as the light absorbing member 8, it is possible to accelerate absorbance of light in the infrared region, and thus effectively reduce the influence of the reflected light. This makes it possible to reduce a measurement error of an output characteristic of the solar cell B caused by re-application of the reflected light to the solar cell B.

It is preferable that an antireflection film (antireflection means) for preventing reflection of simulated sunlight be provided on a surface (in particular, a top surface) of the light absorbing member 8. This suppresses surface reflection of the light absorbing member 8 and thus increases light that travels back and forth (passes) through the light absorbing member 8. This allows the reflected light to be absorbed by the light absorbing member 8 more efficiently. The provision of the antireflection film also makes it possible to reduce light reflected on the top surface of the light absorbing member 8 among the reflected light from the solar cell B, and thus suppress re-application of the reflected light to the solar cell B.

Alternatively, it is preferable that the surface (in particular, the top surface) of the light absorbing member 8 have been subjected to a diffusion treatment for diffusing light. This causes light to be reflected from the surface of the light absorbing member 8 in various directions, so that reflected light that is obliquely applied to the solar cell B is relatively increased. In a case where reflected light enters the solar cell B obliquely, a quantity of power generated is decreased relative to a quantity of power generated in a case where reflected light enters the solar cell B vertically. As a result, an effect similar to reduction in intensity of reflected light re-applied to the solar cell B is achieved. Further, since the reflected light having been diffused on the surface of the light absorbing member 8 enters the light absorbing member 8, an optical path (distance) in which the reflected light travels inside the light absorbing member 8 is relatively increased (reflected light that travels obliquely inside the light absorbing member 8 is increased). This allows reflected light to be absorbed by the light absorbing member 8 more efficiently. With these effects, it is possible to suppress an influence of the reflected light on the solar cell B also in the case where the surface of the light absorbing member 8 has been subjected to the diffusion treatment.

<Optical Path of Reflected Light in Simulated Sunlight Irradiation Apparatus>

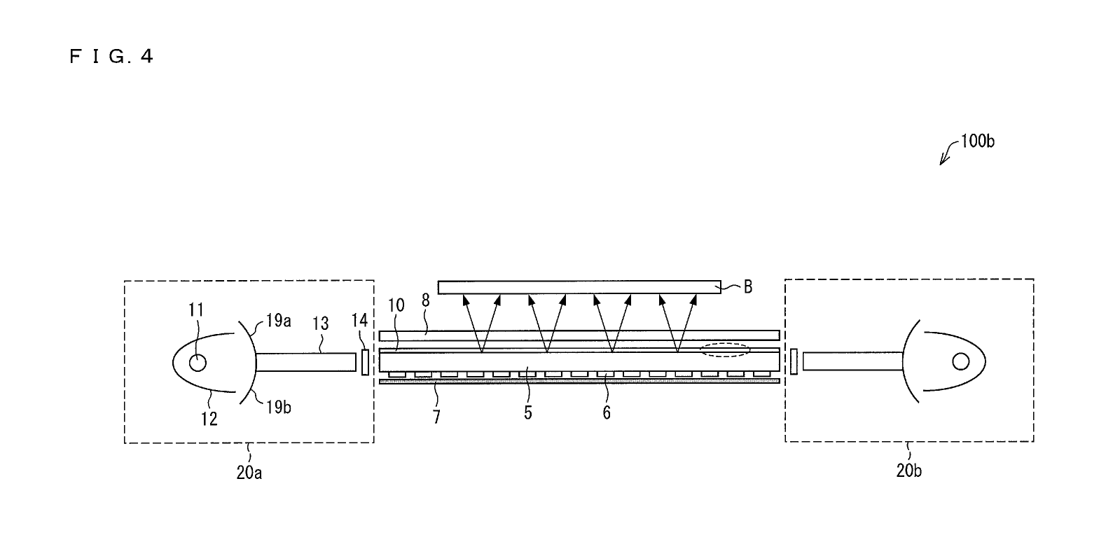

Next, the following discusses, with reference to FIG. 3, an optical path of reflected light in the simulated sunlight irradiation apparatus 100a. FIG. 3 is a schematic view illustrating an optical path of simulated sunlight in the simulated sunlight irradiation apparatus 100a.

As illustrated in FIG. 3, in a case where measurement light emitted from the irradiation surface of the light guide plate 5 is received as it is by the solar cell B without being reflected by the solar cell B, the measurement light passes through the light absorbing member 8 only once in an optical path 31 from the light guide plate 5 to the solar cell B.

In contrast, in a case where reflected light which has been reflected by the solar cell B without being received by the solar cell B is reflected by the reflecting plate 7 and then re-applied to the solar cell B, the reflected light passes through the light absorbing member 8 twice in an optical path 32 in which the reflected light travels after being reflected by the solar cell B until being re-applied to the solar cell B. That is, the reflected light from the solar cell B passes through the light absorbing member 8 both in an optical in which the reflected light travels from the solar cell B to the reflecting plate 7 and in an optical path in which the reflected light travels after being reflected by the reflecting plate 7 until being re-applied to the solar cell B.

Accordingly, light in the infrared region contained in the reflected light is absorbed sufficiently by the light absorbing member 8. This makes it possible to reduce the influence of the reflected light which is re-applied to the solar cell B.

Therefore, the simulated sunlight irradiation apparatus 100a allows a reduction in measurement error of an output characteristic of the solar cell B caused by re-application of the reflected light to the solar cell B.

Note that part of the reflected light from the solar cell may be reflected from a surface of the light guide plate 5 so as to be re-applied to the solar cell B. Also in this case, providing the light absorbing member 8 between the irradiation surface of the light guide plate 5 and the solar cell B causes the reflected light from the solar cell B to pass through the light absorbing member 8 twice in an optical path from a point where the reflected light is reflected from the surface of the light guide plate 5 to a point where the reflected light is re-applied to the solar cell B. That is, the reflected light from the solar cell B passes through the light absorbing member 8 both in an optical path in which the reflected light travels from the solar cell B to the surface of the light guide plate 5 and in an optical path in which the reflected light travels after being reflected from the surface of the light guide plate 5 until being re-applied to the solar cell B.

Therefore, by providing the light absorbing member 8 between the irradiation surface of the light guide plate 5 and the solar cell B, the reflected light from the solar cell B can be efficiently absorbed by the light absorbing member 8.

<Directivity Control in Light Introducing Section>

Next, the following discusses directivity control in the light introducing sections 20a and 20b. The xenon lamp 11 is a non-directional slight source. Accordingly, light emitted from the xenon lamp 11 is diffusion light that diffuses. Accordingly, it is preferable that directivity of the light emitted from the xenon lamp 11 be controlled so that the light emitted from the xenon lamp 11 enters the optical filter 14 at a predetermined incident angle.

In the simulated sunlight irradiation apparatus 100a, a radiation directivity of light emitted from the xenon lamp is controlled by the ellipse mirror 12. Further, the radiation directivity of the light emitted from the xenon lamp 11 is controlled also by the taper coupler 13. The light whose directivity has been thus controlled enters the optical filter 14, in which a spectrum of the light is then adjusted. Subsequently, the light enters the light guide plate 5 as simulated sunlight.

Further, the simulated sunlight irradiation apparatus 100a includes the reflecting members 19a and 19b for the ellipse mirror 12. Accordingly, light that did not enter the taper coupler 13 is reflected by the reflecting members 19a and 19b, then reflected by the ellipse mirror 12 again, and then enters the incident surface of the taper coupler 13. This allows the light emitted from the xenon lamp 11 to be used efficiently, and also allows light having a high directivity to be extracted selectively.

The two opposed surfaces of the taper coupler 13 in the z axis direction in the simulated sunlight irradiation apparatus 100a has a taper shape (trapezoidal shape). That is, a width (cross section) of the taper coupler 13 gradually increases from the incident surface to the exit surface of the taper coupler 13. This structure improves directivity (radiation angle) of the light emitted from the xenon lamp 11 while the light is being reflected a plurality of times on side surfaces of the taper coupler 13. Consequently, light having a high directivity (under control of radiation angle) is caused to exit from the exit surface of the taper coupler 13.

Note that the radiation angle of light emitted from the taper coupler 13 is controlled by an inclination angle of a side surface of the taper coupler 13 and a length of the taper coupler 13 in a direction in which light travels.

Further, in the case where the taper coupler 13 is used, all of the light emitted from the xenon lamp 11 travels through the taper coupler 13. This allows (i) the light emitted from the xenon lamp 11 to travel in an identical direction (directivity of the light is increased) and (ii) the light caused to travel in the identical direction to enter the optical filter 14 with a low loss. Note that the taper coupler 13 may be made of, for example, quartz or the like.

An advantage of increasing the directivity of light by use of the taper coupler 13 is relevant to a structure of the optical filter 14. Specifically, the optical filter 14 has a structure in which a plurality of thin layers are stacked. Accordingly, a characteristic in transmittance varies more as an incident angle of the light entering the optical filter 14 shifts to a greater extent from an angle of normal incident light to the optical filter 14.

In other words, when light having poor directivity enters the optical filter 14, generated simulated light has a spectral distribution that diverges from a spectral distribution of the standard sunlight. However, increasing directivity of light by use of the taper coupler 13, it becomes possible in the optical filer 14 to generate simulated sunlight whose spectral distribution is similar to that of the standard sunlight.

As described above, since the simulated sunlight irradiation apparatus 100a includes the taper coupler 13, directivity of light emitted from the xenon lamp 11 is controlled so that the light enters the optical filter 14 at a predetermined angle. It also becomes possible to suppress a loss in light intensity of the light from the xenon lamp 11 before the light reaches the light guide plate 5.

Further, since the directivity of the light is increased by use of the taper coupler 13, it becomes possible to generate simulated sunlight whose spectral distribution is similar to that of the standard sunlight. This makes it possible to irradiate the solar cell B with simulated sunlight whose irradiance (light intensity) and spectrum are closer to those of the standard sunlight.

Note that it is preferable that directivity of light be controlled by use of the taper coupler 13 in such a manner that the light is caused to travel inside the taper coupler 13 so that a maximum radiation angle of the light is not more than 30°. This increases a ratio of a component which is contained in the light inside the taper coupler 13 and emitted with a directivity of 0° (that is, perpendicular to the exit surface of the taper coupler 13) is increased as the light travels from an incident end to an exit end.

Similarly, it is also preferable that the ellipse mirror 12 be set so that light emitted from the xenon lamp 11 is collected by the ellipse mirror 12 so as to travel in a direction with a radiation angle of not more than 30° with respect to an angle of normal incidence (0° incidence) to the incident end of the taper coupler 13.

<Modified Examples of Simulated Sunlight Irradiation Apparatus>

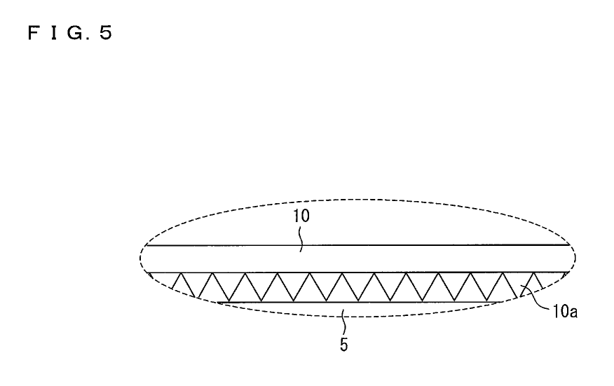

Next, the following discusses, with reference to FIGS. 4 through 9, modified examples of the simulated sunlight irradiation apparatus 100a in accordance with the present embodiment.

### Modified Example 1

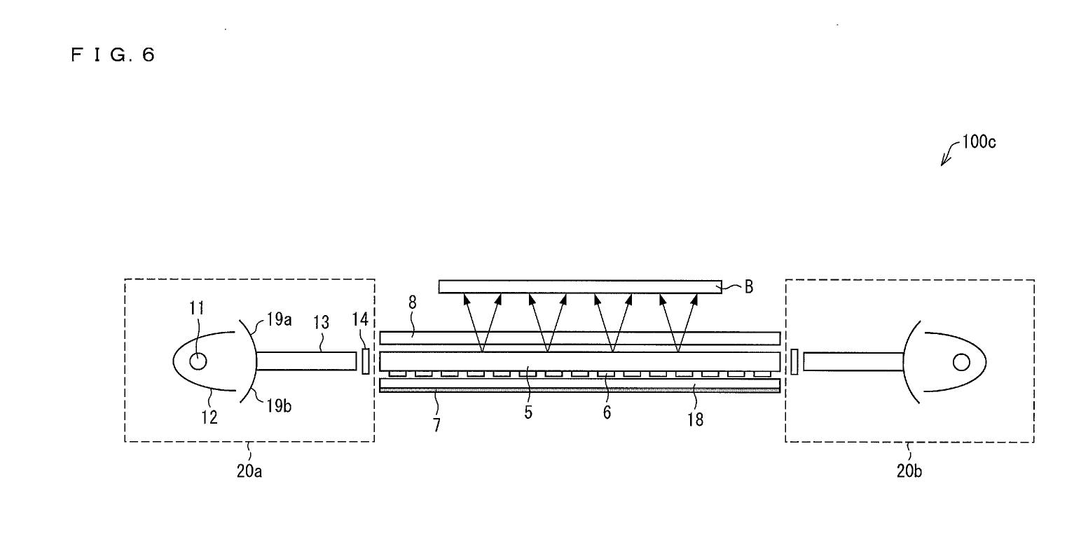

First, the following discuss, with reference to FIGS. 4 and 5, a simulated sunlight irradiation apparatus 100b, which is a first modified example of the simulated sunlight irradiation apparatus 100a in accordance with the present embodiment. The simulated sunlight irradiation apparatus 100b is different from the simulated sunlight irradiation apparatus 100a mainly in that a prism sheet 10 is provided on the top surface of the light guide plate 5.

FIG. 4 is a side view illustrating the simulated sunlight irradiation apparatus 100b, which is the first modified example, and FIG. 5 is an enlarged view illustrating a portion within a broken line illustrated in FIG. 4. As illustrated in FIG. 4, the simulated sunlight irradiation apparatus 100b is arranged such that the prism sheet 10, which is an optical member having photorefractivity, is provided on the top surface of the light guide plate 5.

The prism sheet 10 includes a prism structure 10a on a surface of the prism sheet 10 on a light guide plate 5 side. The prism sheet 10 is capable of generating, by means of a photorefractive effect, many components of light perpendicular to the irradiation surface of the light guide plate 5. This makes it possible to irradiate simulated sunlight more efficiently from the light guide plate 5 toward the solar cell B.

However, in a case where the prism sheet 10 is provided on the top surface of the light guide plate 5 as in the simulated sunlight irradiation apparatus 100b, reflected light from the solar cell B tends to be reflected from a surface of the prism sheet 10 so as to be re-applied to the solar cell B. Even in this case, by providing the light absorbing member 8 between the prism sheet 10 and the solar cell B, light that is re-applied to the solar cell B among the reflected light can be reduced.

### Modified Example 2

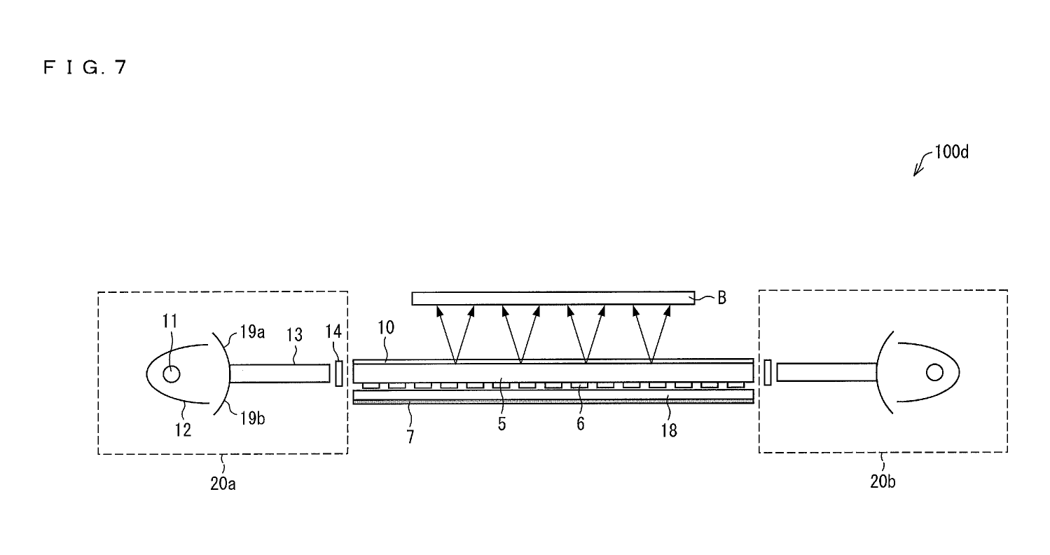

Next, the following discusses, with reference to FIG. 6, a simulated sunlight irradiation apparatus 100c, which is a second modified example of the simulated sunlight irradiation apparatus 100a in accordance with the present embodiment. The simulated sunlight irradiation apparatus 100c is different from the simulated sunlight irradiation apparatus 100a mainly in that a light absorbing member is provided also below the light guide plate 5 as a light absorbing member 18.

FIG. 6 is a side view illustrating the simulated sunlight irradiation apparatus 100c, which is the second modified example. As illustrated in FIG. 6, the simulated sunlight irradiation apparatus 100c further includes the light absorbing member 18 provided below the light guide plate 5, as well as the light absorbing member 8 provided above the light guide plate 5.

The light absorbing member 18 is provided between the light guide plate 5 and the reflecting plate 7, and the light absorbing member 18 and the reflecting plate 7 are integrally formed. This makes it possible to reduce a width of the simulated sunlight irradiation apparatus 100c along a height direction thereof, and thus reduce a size of the simulated sunlight irradiation apparatus 100c.

For example, by (i) forming a reflective film on a soda glass substrate and (ii) disposing the soda glass substrate so that a side of the soda glass substrate on which side no reflective film is formed faces up, the soda glass substrate can serve as the light absorbing member 18.

Since the light absorbing member 18 is further provided below the light guide plate 5 as well as the light absorbing member 8 provided above the light guide plate 5, (i) reflected light having passed through the light guide plate 5 and (ii) reflected light having been reflected from the reflecting plate 7 after passing through the light guide plate 5 can be absorbed by the light absorbing member 18. This makes it possible to further reduce light re-applied to the solar cell B among the reflected light.

### Modified Example 3

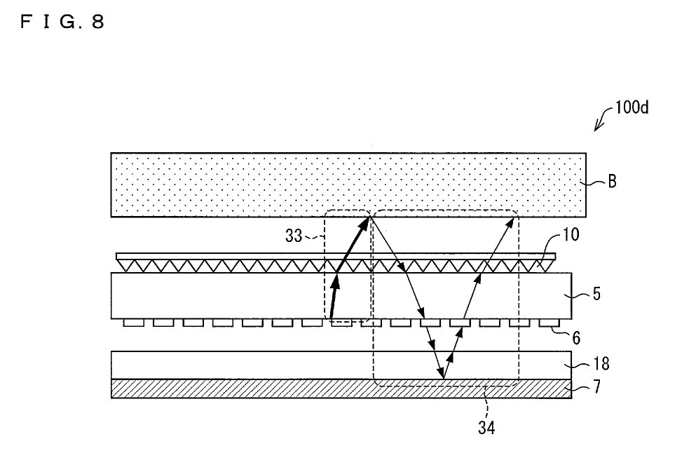

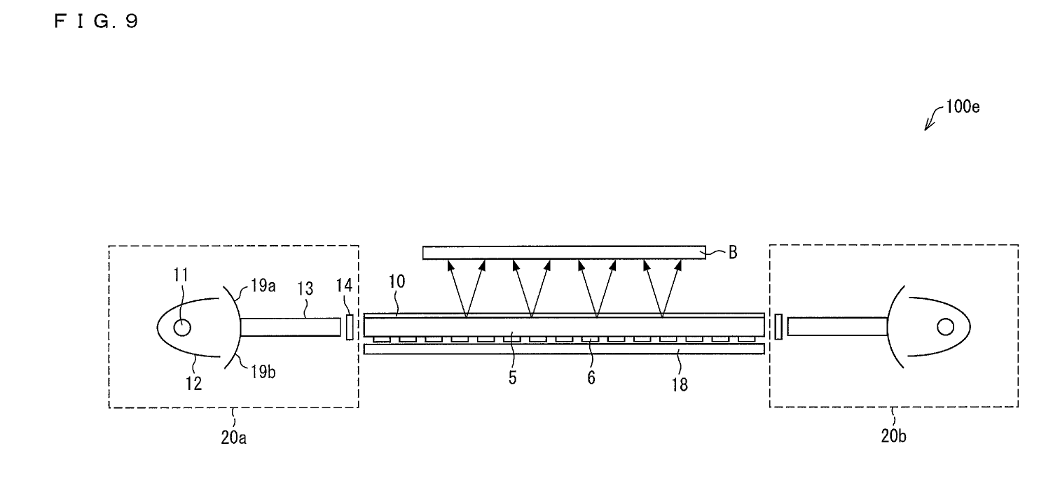

Next, the following discusses, with reference to FIGS. 7 and 8, a simulated sunlight irradiation apparatus 100d, which is a third modified example of the simulated sunlight irradiation apparatus 100a in accordance with the present embodiment. The simulated sunlight irradiation apparatus 100d is different from the simulated sunlight irradiation apparatus 100a mainly in that (i) the prism sheet 10 is provided on the top surface of the light guide plate 5 and (ii) a light absorbing member is provided only below the light guide plate 5 as a light absorbing member 18.

FIG. 7 is a side view illustrating the simulated sunlight irradiation apparatus 100d, which is the third modified example. As illustrated in FIG. 7, the simulated sunlight irradiation apparatus 100d is arranged such that the prism sheet 10 is provided on the top surface of the light guide plate 5. As described in Modified Example 1, in a case where the prism sheet 10 is provided on the top surface of the light guide plate 5, reflected light from the solar cell B tends to be reflected from a surface of the prism sheet 10 so as to be re-applied to the solar cell B.

In view of this, the simulated sunlight irradiation apparatus 100d includes an antireflection film formed on the surface of the prism sheet 10, so that less of the reflected light is reflected from the surface of the prism sheet 10.

In this case, the reflected light from the solar cell B passes through the prism sheet 10 more easily. It is therefore particularly preferable to provide the reflecting plate 7 below the light guide plate 5 from the viewpoint of preventing a decrease in light output value of the simulated sunlight irradiation apparatus 100d.

FIG. 8 is a schematic view illustrating an optical path of simulated sunlight in the simulated sunlight irradiation apparatus 100d. As illustrated in FIG. 8, in a case where measurement light emitted from the irradiation surface of the light guide plate 5 is received by the solar cell B without being reflected by the solar cell B, the measurement light is received by the solar cell B as it is without passing through the light absorbing member 18 in an optical path 33 from the light guide plate 5 to the solar cell B.

In contrast, in a case where reflected light which has been reflected by the solar cell B without being received by the solar cell B is reflected by the reflecting plate 7 and then re-applied to the solar cell B, the reflected light passes through the light absorbing member 18 twice in an optical path 34 in which the reflected light travels after being reflected by the solar cell B until being re-applied to the solar cell B. That is, the reflected light from the solar cell B passes through the light absorbing member 18 both in an optical path in which the reflected light travels from the solar cell B to the reflecting plate 7 and in an optical path in which the reflected light travels after being reflected by the reflecting plate 7 until being re-applied to the solar cell B. Specifically, the reflected light having passed through the light guide plate 5 passes through the light absorbing member 18 both in an optical path in which the reflected light travels from the light guide plate 5 to the reflecting plate 7 and in an optical path in which the reflected light travels to the light guide plate 5 after being reflected by the reflecting plate 7. While the reflected light passes through the light absorbing member 18, light in the infrared region contained in the reflected light is sufficiently absorbed by the light absorbing member 18. This makes it possible to reduce an influence of the reflected light re-applied to the solar cell B.

Further, providing the light absorbing member 18 only below the light guide plate 5 causes the measurement light emitted from the top surface of the light guide plate 5 to be applied directly to the solar cell B without passing through the light absorbing member 18. This allows the measurement light to maintain an original spectrum of the measurement light, without being affected by a light-absorbing function of the light absorbing member 18. This facilitates spectrum adjustment of the measurement light.

Note that, in a case where the light absorbing member 18 made of soda glass or the like is provided to the reflecting plate 7, it is preferable that an antireflection film be formed on a surface of the light absorbing member 8 in order to suppress reflection of the reflected light on a surface of the light absorbing member 18. With this arrangement, re-application of the reflected light to the solar cell without passing the reflected light through the light absorbing member 18 can be suppressed.

### Modified Example 4

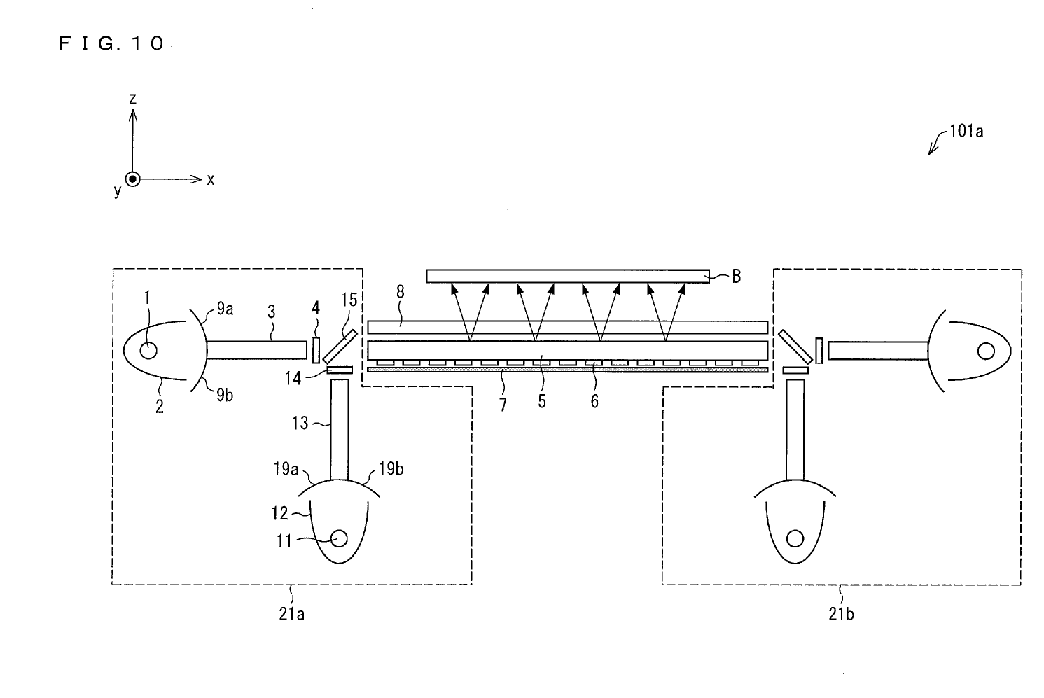

Next, the following discusses, with reference to FIG. 9, a simulated sunlight irradiation apparatus 100e, which is a fourth modified example of the simulated sunlight irradiation apparatus 100a in accordance with the present embodiment. The simulated sunlight irradiation apparatus 100e is different from the simulated sunlight irradiation apparatus 100a mainly in that the prism sheet 10 is provided on the top surface of the light guide plate 5 and a light absorbing member is provided only below the light guide plate 5 as a light absorbing member 18. That is, the simulated sunlight irradiation apparatus 100e has the same arrangement as that of the simulated sunlight irradiation apparatus 100d illustrated in FIG. 7, except that the reflecting plate 7 is omitted.

FIG. 9 is a side view illustrating the simulated sunlight irradiation apparatus 100e, which is the fourth modified example. As illustrated in FIG. 9, the simulated sunlight irradiation apparatus 100d has the same arrangement as that of the simulated sunlight irradiation apparatus 100d illustrated in FIG. 7, except that the reflecting plate 7 is omitted.

In a case where the reflected light from the solar cell B is reflected by each of the simulated sunlight irradiation apparatuses 100a through 100d and then re-applied to the solar cell B, a light intensity of light reflected from the reflecting plate 7 provided below the light guide plate 5 is significantly higher than a light intensity of light reflected from the prism sheet 10, the light guide plate 5, and the like.

In view of this, in the simulated sunlight irradiation apparatus 100e, (i) the reflecting plate 7 provided below the light guide plate 5 is omitted and (ii) the light absorbing member 18 is constituted by a material having a very high absorptance, for example, a non-reflecting sheet having an absorptance of 90% or more (e.g., SOMABLACK (manufactured by SOMAR Corp.) etc.).

By providing the light absorbing member 18 having a high light absorptance, the reflected light having passed through the prism sheet 10 and the light guide plate 5 after being reflected from the solar cell B can be absorbed by the light absorbing member 18 almost completely. This allows a significant reduction in light re-applied to the solar cell B among the reflected light.

### Conclusion of Embodiment 1

As described above, each of the simulated sunlight irradiation apparatuses 100a through 100e in accordance with the present embodiment includes (i) the xenon lamp emitting light, (ii) the optical filter 14 adjusting a spectrum of the light emitted from the xenon lamp 11, (iii) the light guide plate 5 which the light whose spectrum has been adjusted by the optical filter 14 enters, the light guide plate 5 having an irradiation surface and a counter surface opposite to the irradiation surface, (iv) the light extracting section 6 which causes the light having entered the light guide plate 5 to be extracted through the irradiation surface of the light guide plate toward the solar cell B, and (v) at least one of the light absorbing members 8 and 18 which are respectively provided on an irradiation surface side and a counter surface side of the light guide plate 5, each of the light absorbing members 8 and 18 absorbing light in a predetermined wavelength region.

Each of the simulated sunlight irradiation apparatuses 100a through 100e includes at least one of the light absorbing members 8 and 18, which are provided respectively on the irradiation surface side of the light guide plate 5 and on the counter surface side of the light guide plate 5 opposite to the irradiation surface, and each of which absorbs light in the same wavelength region as that of the reflected light. As such, by controlling, in accordance with the wavelength region of the reflected light, a wavelength region of light absorbed by the light absorbing members 8 and 18, the reflected light can be absorbed by use of the light absorbing members 8 and 18.

Therefore, the present embodiment makes it possible to provide the simulated sunlight irradiation apparatuses 100a through 100e each of which suppresses re-application, to the solar cell B, of reflected light from the solar cell B. This makes it possible to reduce a measurement error as described above of an output characteristic of the solar cell B.

### Embodiment 2

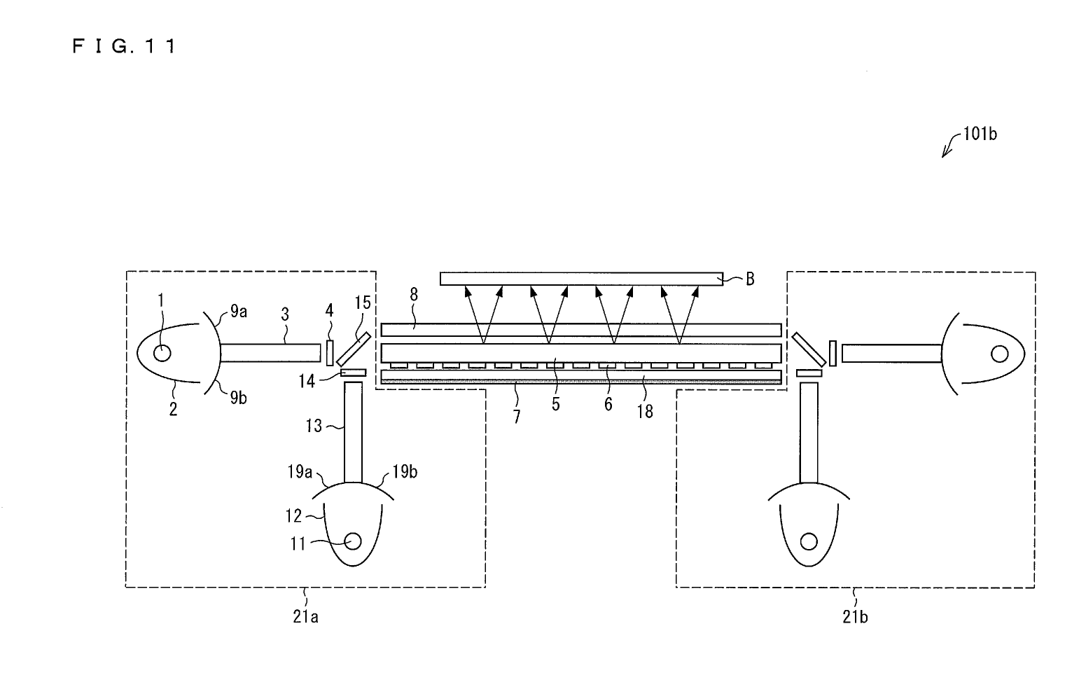

The following discusses, with reference to FIGS. 10 through 12, another embodiment of the simulated sunlight irradiation apparatus of the present invention.

For easy explanation, the same reference signs will be given to members having the same function as a member illustrated in the figures of Embodiment 1, and descriptions on such a member will be omitted.

A simulated sunlight irradiation apparatus 101a in accordance with the present embodiment is different from the simulated sunlight irradiation apparatus 100a of Embodiment 1 in that simulated sunlight with which the solar cell B is irradiated is generated by use of two rays of light which are different from each other in spectrum, in order for the simulated sunlight to have a spectral distribution more similar to a spectral distribution of actual sunlight.

<Arrangement of Simulated Sunlight Irradiation Apparatus>

First, the following discusses, with reference to FIG. 10, an arrangement of the simulated sunlight irradiation apparatus 101a in accordance with the present embodiment. FIG. 10 is a side view illustrating a substantial arrangement of the simulated sunlight irradiation apparatus 101a in accordance with the present embodiment. As illustrated in FIG. 10, the simulated sunlight irradiation apparatus 101a includes light introducing sections 21a and 21b, the light guide plate 5, the light extracting section 6, the reflecting plate 7, and the light absorbing member 8. The simulated sunlight irradiation apparatus 101a has the same arrangement as that of the simulated sunlight irradiation apparatus 101a in accordance with Embodiment 1 except that the light introducing sections 21a and 21b are provided in place of the light introducing sections 20a and 20b. As such, the following description will discuss the light introducing sections 21a and 21b in detail, and descriptions on other members will be omitted.

(Light Introducing Sections)

The light introducing sections 21a and 21b each generate simulated sunlight by adjusting spectra of two rays of light emitted from respective light sources and then mixing the two rays of light. Then, the light introducing sections 21a and 21b each emit the thus generated simulated sunlight to the light guide plate 5.

Note that the light introducing section 21a and the light introducing section 21b have the same arrangement. As such, the following description discusses only the arrangement of the light introducing section 20a.

The light introducing section 21a includes a halogen lamp (first light source) 1, an ellipse mirror 2, reflecting members 9a and 9b, a taper coupler 3, an optical filter (first spectrum adjusting member) 4, a xenon lamp (second light source) 11, an ellipse mirror 12, reflecting members 19a and 19b, a taper coupler 13, an optical filter (second spectrum adjusting member) 14, and a wavelength selecting filter (wavelength selecting member) 15.

That is, the light introducing section 21a has the same arrangement as that of the light introducing section 20a described in Embodiment 1 except that the halogen lamp 1, the ellipse mirror 2, the reflecting members 9a and 9b, the taper coupler 3, the optical filter 4, and the wavelength selecting filter 15 are added.

In the light introducing section 21a, light emitted from the halogen lamp 1 and light emitted from the xenon lamp 11 are selected and mixed by the wavelength selecting filter 15 so as to generate simulated sunlight. Then, the light introducing section 21a irradiates an end surface (incident plane) of the light guide plate 5 with the thus generated simulated sunlight.

More specifically, the halogen lamp 1 and the xenon lamp 11 emit light having spectral distributions required for generation of the simulated sunlight. The light emitted from the halogen lamp 1 and the light emitted from the xenon lamp 11 differ from each other in spectral distribution. The halogen lamp 1 emits much long-wavelength light necessary for the simulated sunlight. Meanwhile, the xenon lamp 11 emits much short-wavelength light necessary for the simulated sunlight.

The ellipse mirror 2 collects light emitted from the halogen lamp 1, and reflects the thus collected light toward the taper coupler 3. The ellipse mirror 2 is provided so that the halogen lamp 1 is surrounded by the ellipse mirror 2 in all directions except a direction in which light is emitted toward the taper coupler 3. The ellipse mirror 2 on a halogen lamp 1 side is made of aluminum and has an elliptical reflective surface on which gold deposition film is formed.

The reflecting members 9a and 9b are provided so as to enclose the incident surface of the taper coupler 3, and light that did not enter an incident surface of the taper coupler 3, among the light directly emitted from the xenon lamp 1 and the light reflected from the ellipse mirror 2, is reflected by the reflecting members 9a and 9b toward the ellipse mirror 2.

The taper coupler 3 is provided between the halogen lamp 1 and the optical filter 4. One end of the taper coupler 3 is provided so as to be close to the halogen lamp 1, and the other end is provided so as to be close to the optical filter 4.

The taper couplers 3 and 13 are disposed so that a direction (x axis direction) of light emitted from the taper coupler 3 (light from the halogen lamp 1) makes an angle of 90° with a direction (z axis direction) of light emitted from the taper coupler 13 (light from the xenon lamp 11).

The optical filter 4 is provided so as to be close to an exit surface of the taper coupler 3 for the halogen lamp 1.

The optical filter 4 adjusts a spectral distribution of light of the halogen lamp 1 exiting from the taper coupler 3. Similarly, the optical filter 14 is provided so as to be close to an exit surface of the taper coupler 13 for the xenon lamp 11. The optical filter 14 adjusts a spectral distribution of light of the xenon lamp 11 exiting from the taper coupler 13. The light whose spectra are adjusted by the optical filters 4 and 14 enter the wavelength selecting filter 15.

The wavelength selecting filter 15 has a function of selecting wavelengths. In other words, the wavelength selecting filter 15 not only selects (extracts) light necessary for simulated sunlight from light emitted from the halogen lamp 1 and the xenon lamp 11, but also generates the simulated sunlight by mixing the thus selected light.

More specifically, the wavelength selecting filter 15 reflects light having wavelengths less than a predetermined wavelength (short wavelengths shorter than the predetermined wavelength), while transmitting light having wavelengths equal to and more than the predetermined wavelength (long wavelengths longer than the predetermined wavelength). In other words, the wavelength selecting filter 15 has a function of transmitting long-wavelength light necessary for the simulated sunlight while reflecting short-wavelength light necessary for the simulated sunlight. Thereby, the wavelength selecting filter 15 generates the simulated sunlight by mixing the long-wavelength light and the short-wavelength light.

More specifically, halogen light (first light) emitted from the halogen lamp 1 and xenon light (second light) emitted from the xenon lamp 11 enter the wavelength selecting filter 15. The wavelength selecting filter 15 synthesizes the simulated sunlight by (i) selecting light of necessary components (spectra) from the halogen light and the xenon light which have entered the wavelength selecting filter 15 and (ii) mixing the light thus selected.

More specifically, the halogen light emitted from the halogen lamp 1 includes many long-wavelength components necessary for the simulated sunlight. Meanwhile, the xenon light emitted from the xenon lamp 11 includes many short-wavelength components necessary for the simulated sunlight. As such, for the wavelength selecting filter 15, a boundary wavelength is set in a range of not shorter than 600 nm but not longer than 800 nm. Accordingly, the wavelength selecting filter 15 reflects light having wavelengths shorter than this boundary wavelength, while transmitting light having wavelengths equal to or longer than the boundary wavelength.

That is, the wavelength selecting filter 15 transmits only light (light of long-wavelength components) having wavelengths equal to and longer than the boundary wavelength among the halogen light emitted from the halogen lamp 1. Meanwhile, the wavelength selecting filter 15 reflects only light (light of short-wavelength components) having wavelengths shorter than the boundary wavelength among the xenon light emitted from the xenon lamp 11.

Assume a case where, for example, for light having wavelengths shorter than 700 nm, the light from the xenon lamp 11 is employed, while for light having wavelengths of 700 nm and longer, the light from the halogen lamp 1 is employed. In this case, the boundary wavelength between wavelengths for reflection and transmission of the wavelength selecting filter 15 is at the wavelength of 700 nm. In other words, the wavelength selecting filter 15 has a characteristic in which light having wavelengths shorter than the wavelength of 700 nm is reflected while light having wavelengths of 700 nm and longer is transmitted. This allows light having wavelengths necessary for generation of simulated sunlight to be selected by the wavelength selecting filter 15. The light thus selected is mixed and enters the light guide plate 5 as simulated sunlight.

Note that the boundary wavelength of light for reflection or transmission of the wavelength selecting filter 15 may be set as appropriate. Further, the wavelength selecting filter 15 can be a wavelength dependent mirror or filter. For example, a cold mirror, a hot mirror, or the like can be used as the wavelength selecting filter 15.

As described above, the wavelength selecting filter 15 selects (i) long-wavelength light necessary for generation of simulated sunlight which long-wavelength light is contained in the halogen light emitted from the halogen lamp 1 and (ii) short-wavelength light necessary for generation of the simulated sunlight which short-wavelength light is contained in the xenon light emitted from the xenon lamp 11. At this time, light of short-wavelength components of the halogen lamp 1 not under spectral control is removed. Similarly, light of long-wavelength components of the xenon lamp 11 not under spectral control is removed.

As described above, the simulated sunlight irradiation apparatus 101a includes the halogen lamp 1 and the xenon lamp 11, and generates the simulated sunlight by mixing light emitted from the halogen lamp 1 and the xenon lamp 11 under spectral control. Accordingly, the simulated sunlight irradiation apparatus 10 la is capable of (i) generating simulated sunlight having a spectrum much closer to a spectrum of actual sunlight than a spectrum of simulated sunlight generated by the simulated sunlight irradiation apparatus 100a in accordance with Embodiment 1 is and (ii) irradiating the solar cell B with the simulated sunlight thus generated.

In the simulated sunlight irradiation apparatus 101a, re-application of reflected light to the solar cell B can be suppressed by controlling a wavelength region of light absorbed by the light absorbing member 8 so that the light absorbing member 8 absorbs reflected light having wavelengths longer than the boundary wavelength.

Note that in the simulated sunlight irradiation apparatus 101a, the halogen lamp 1 and the xenon lamp 11 are employed as light sources for obtaining simulated sunlight. However, kinds of the light sources and a combination of the light sources are not limited to the above kinds and combination, but may be selected as appropriate so that a spectrum of the simulated sunlight becomes similar or identical to that of the standard sunlight. For example, bar light sources or the like may be employed in place of the halogen lamp 1 and the xenon lamp 11.

<Modified Examples of Simulated Sunlight Irradiation Apparatus>

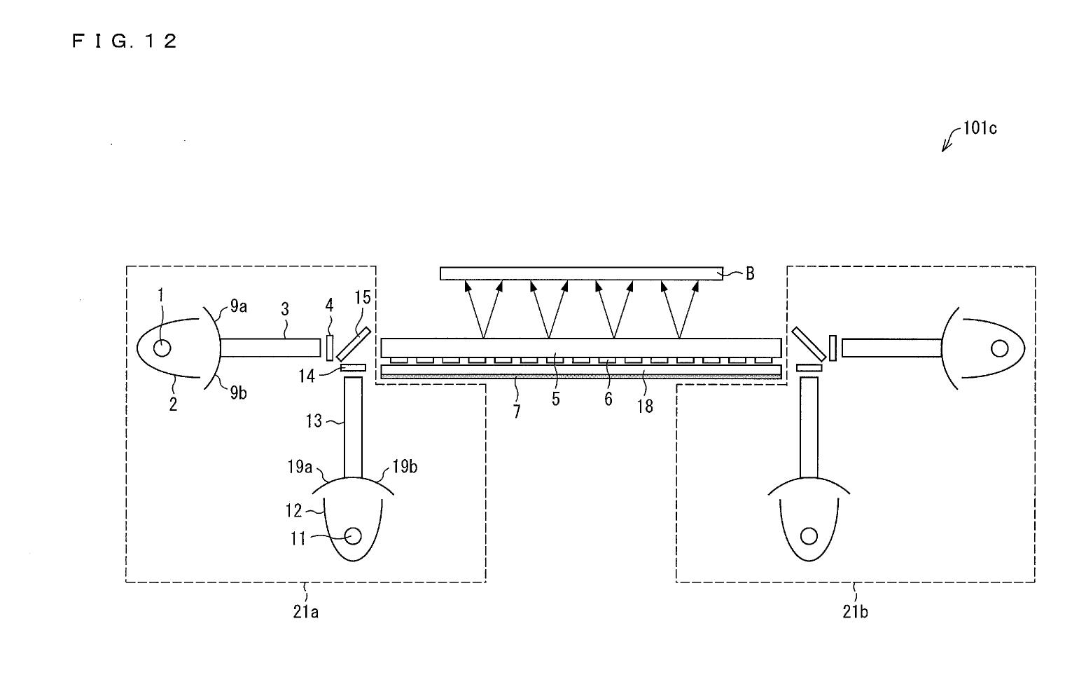

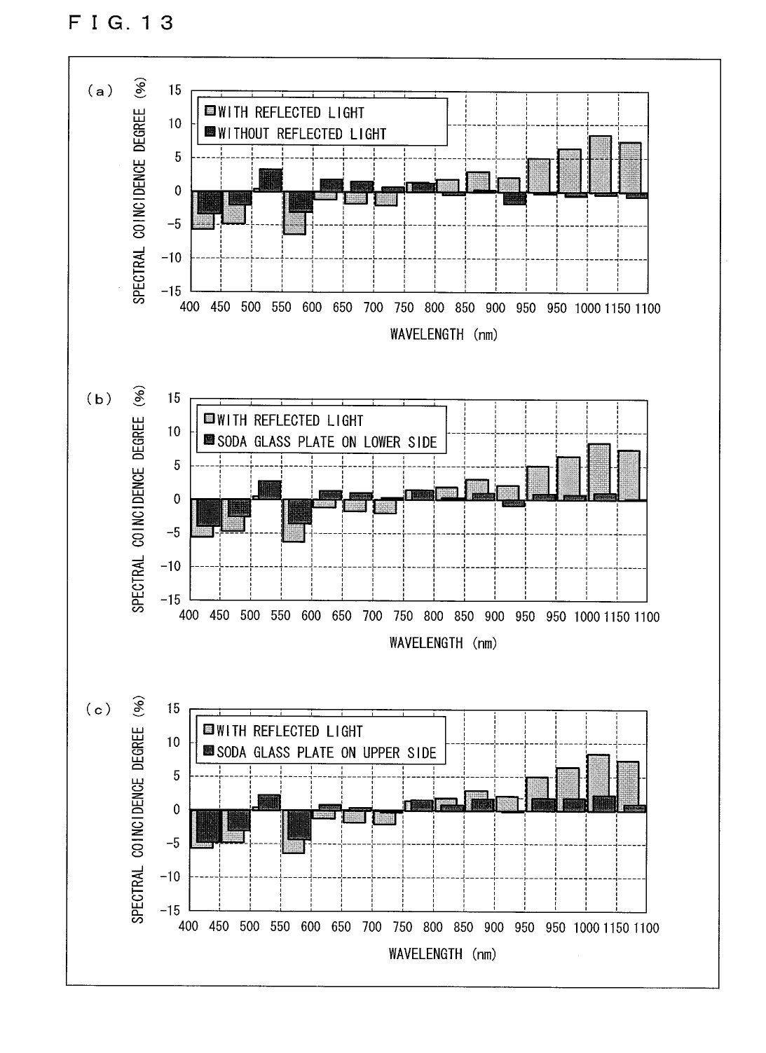

Next, the following discusses, with reference to FIGS. 11 and 12, modified examples of the simulated sunlight irradiation apparatus 101a in accordance with the present embodiment.

### Modified Example 1

First, the following discusses, with reference to FIG. 11, a simulated sunlight irradiation apparatus 101b, which is a first modified example of the simulated sunlight irradiation apparatus 101a in accordance with the present embodiment. The simulated sunlight irradiation apparatus 101b is different from the simulated sunlight irradiation apparatus 101a mainly in that a light absorbing member is provided also below the light guide plate 5 as a light absorbing member 18.

FIG. 11 is a side view illustrating the simulated sunlight irradiation apparatus 101b, which is the first modified example. As illustrated in FIG. 11, the simulated sunlight irradiation apparatus 101b further includes the light absorbing member 18 below the light guide plate 5, as well as the light absorbing member 8 above the light guide plate 5.

The light absorbing member 18 is provided between the light guide plate 5 and the reflecting plate 7, and the light absorbing member 18 and the reflecting plate 7 are integrally formed. This makes it possible to reduce a width of the simulated sunlight irradiation apparatus 101b along a height direction thereof, and thus reduce a size of the simulated sunlight irradiation apparatus 101b.

Since the light absorbing member 18 is thus further provided below the light guide plate 5 as well as the light absorbing member 8 above the light guide plate 5, (i) reflected light having passed through the light guide plate 5 and (ii) reflected light having been reflected from the reflecting plate 7 after passing through the light guide plate 5 can be absorbed by the light absorbing member 18. This makes it possible to further reduce reflected light that is re-applied to the solar cell B.

### Modified Example 2

Next, the following discusses, with reference to FIG. 12, a simulated sunlight irradiation apparatus 101c, which is a second modified example of the simulated sunlight irradiation apparatus 101a in accordance with the present embodiment. The simulated sunlight irradiation apparatus 101c is different from the simulated sunlight irradiation apparatus 101a mainly in that a light absorbing member is provided only below the light guide plate 5 as a light absorbing member 18.

FIG. 12 is a side view illustrating the simulated sunlight irradiation apparatus 101c, which is the second modified example. As illustrated in FIG. 12, the simulated sunlight irradiation apparatus 101c is arranged such that the light absorbing member 18 is provided only below the light guide plate 5.

Reflected light from the solar cell B can be reflected on the top surface of the light guide plate 5 so as to be re-applied to the solar cell B. As such, in the simulated sunlight irradiation apparatus 101c, an antireflection film is formed on the top surface of the light guide plate 5, in order for the reflected light from the solar cell B to pass through the light guide plate 5 more easily.

In this case, the reflected light from the solar cell B passes through the light guide plate 5 more easily. It is therefore particularly preferable to provide the reflecting plate 7 below the light guide plate 5 from the viewpoint of preventing a decrease in light output value of the simulated sunlight irradiation apparatus 101c.

With this arrangement, the reflected light having passed through the light guide plate 5 passes through the light absorbing member 18 twice when the reflected light (i) is reflected from the light the reflecting plate 7 and (ii) then re-enters the light guide plate 5. While the reflected light passes through the light absorbing member 18, light in the infrared region contained in the reflected light is sufficiently absorbed by the light absorbing member 18. This makes it possible to reduce an influence of reflected light that is re-applied to the solar cell B.

Further, providing the light absorbing member 18 only below the light guide plate 5 causes the measurement light emitted from the top surface of the light guide plate 5 to be applied directly to the solar cell B without passing through the light absorbing member 18. This allows the measurement light to maintain an original spectrum of the measurement light, without being affected by a light-absorbing function of the light absorbing member 18. This facilitates spectrum adjustment of the measurement light.

Further, by causing the light absorbing member 18 to absorb light having wavelengths longer than the boundary wavelength, light selected from the xenon light can be applied to the solar cell B while a spectrum of the light selected is maintained. Accordingly, adjustment of light intensity or design of the optical filter 4 in consideration of an influence of the light-absorbing function of the light absorbing member 18 is required only for members on a halogen lamp 1 side. Therefore, design, adjustment, and the like of members of the light introducing section 21a can be easily performed.

### Other Modified Examples

Like the simulated sunlight irradiation apparatus 100d illustrated in FIG. 7, the simulated sunlight irradiation apparatus 101a in accordance with Embodiment 2 can also be arranged such that (i) the prism sheet 10 is provided on the top surface of the light guide plate 5 and (ii) a light absorbing member is provided only below the light guide plate 5 as a light absorbing member 18.

In this case, reflected light from the solar cell B is reflected on a surface of the prism sheet 10 provided on the top surface of the light guide plate 5, so that a light intensity of light re-applied to the solar cell B is increased. It is therefore preferable to form an antireflection film on the surface of the prism sheet 10 so as to prevent the increase in light intensity of the light re-applied. As a result, the reflected light from the solar cell B passes through the prism sheet 10 more easily. As such, by providing the reflecting plate 7 below the light guide plate 5, a decrease in light output value of the simulated sunlight irradiation apparatus can be prevented.

Further, like the simulated sunlight irradiation apparatus 100e illustrated in FIG. 9, the simulated sunlight irradiation apparatus 101a in accordance with Embodiment 2 can also have an arrangement in which the reflecting plate 7 of the simulated sunlight irradiation apparatus 100d illustrated in FIG. 7 is omitted.

In this case, by employing, as the light absorbing member 18, a material having a very high absorptance such as a non-reflecting sheet having an absorptance of 90% or more (e.g., SOMABLACK (manufactured by SOMAR Corp.) etc.), reflected light from the solar cell B having passed through the prism sheet 10 and the light guide plate 5 can be almost completely absorbed by the light absorbing member 18. This allows a significant reduction in reflected light that is re-applied to the solar cell B.

### Conclusion of Embodiment 2

As described above, each of the simulated sunlight irradiation apparatus 101a through 101c in accordance with the present embodiment includes (i) the halogen lamp 1 emitting halogen light, (ii) the xenon lamp 11 emitting xenon light having a spectral distribution different from that of the halogen light, (iii) the optical filter 4 adjusting a spectrum of the halogen light, (iv) the optical filter 14 adjusting a spectrum of the xenon light, and (v) the wavelength selecting filter 15 which the halogen light whose spectrum has been adjusted by the optical filter 4 and the xenon light whose spectrum has been adjusted by the optical filter 14 enter, the wavelength selecting filter 15 (i) selecting light from the halogen light and the xenon light each of which has entered the wavelength selecting filter 15, (ii) mixing the light thus selected, and (iii) causing the light thus mixed to enter the light guide plate 5.

The present embodiment makes it possible to provide the simulated sunlight irradiation apparatus 101a through 101c which are, by controlling wavelength regions of light absorbed by the respective light absorbing members 8 and 18 to be longer than the boundary wavelength, capable of (i) suppressing re-application of reflected light to the solar cell B and (ii) emitting simulated sunlight having a spectrum very close to a spectrum of actual sunlight.

Further, by employing an arrangement in which the light absorbing member 18 having a high absorptance is provided below the light guide plate 5 as the light absorbing member 8, it is possible to provide a simulated sunlight irradiation apparatus which is capable of emitting simulated sunlight having a spectrum very close to a spectrum of actual sunlight.

### Example

The following discusses, with reference to (a) through (c) of FIG. 13, an example in which the simulated sunlight irradiation apparatus of the present invention was used.

In the present example, the simulated sunlight irradiation apparatus 101a illustrated in FIG. 10 and the simulated sunlight irradiation apparatus 101c illustrated in FIG. 12 were used to carry out a simulation to verify a degree of spectral coincidence of simulated sunlight with which the solar cell B was irradiated (spectral difference between the standard sunlight and the simulated sunlight) in each of (i) a case where the light absorbing member 8 was provided between the light guide plate 5 and the solar cell B and (ii) a case where no light absorbing member 8 was provided between the light guide plate 5 and the solar cell B.

(a) through (c) of FIG. 13 are graphs showing results of simulations for verifying light absorption effects of the light absorbing members (soda glass) 8 and 18 in the present example. (a) through (c) of FIG. 13 show degrees of spectral coincidence (that is, spectral differences between simulated sunlight and the standard sunlight) obtained in the simulations in the present example. Note that “0” along a vertical axis (%) in each of (a) through (c) of FIG. 13 represents a case where there is no spectral difference between the standard sunlight and the simulated sunlight, and means that an ideal spectrum was obtained.

In verification data of each of (a) through (c) of FIG. 13, data indicated by a state “WITH REFLECTED LIGHT” shows a degree of spectral coincidence obtained in a case where there is reflected light from the solar cell B which is installed at a measurement position in a state where neither of the light absorbing members 8 and 18 is provided.

A state “WITHOUT REFLECTED LIGHT” in (a) of FIG. 13 represents a state where (i) the solar cell B is not installed at a measurement position (no reflected light is generated), (ii) neither of the light absorbing members 8 and 18 is provided, and (iii) a degree of spectral coincidence is adjusted so as to achieve a state where an MS class according to JIS (within ±5%, which is a level required in a high-precision simulated sunlight irradiation apparatus) is satisfied (a state where the degree of spectral coincidence is adjusted to 3.3% (a maximum value in a predetermined wavelength band of 350 nm to 1100 nm, and in this case, 3.3% in a wavelength band of 450 nm to 500 nm), which is very close to an ideal state).

Note that, in the verification data of each of (a) through (c) of FIG. 13, the data indicated by the state “WITH REFLECTED LIGHT” is also a result of a simulation of degree of spectral coincidence which would be obtained if the state “WITHOUT REFLECTED LIGHT” in (a) of FIG. 13 were changed in such a manner that the solar cell B is installed in the measurement position while the light absorbing members 8 and 18 remain unprovided.

Comparison of these data shows that, in the case where the solar cell B is installed at the measurement position (the state “WITHOUT REFLECTED LIGHT”), the spectrum of the simulated sunlight is disturbed so as to deviate significantly from the ideal state, due to an influence of light in the infrared region contained in the reflected light from the solar cell B.

Provision of the solar cell B degrades the degree of spectral coincidence from 3.3% (a maximum value within the predetermined wavelength band of 350 nm to 1100 nm, and in this case, 3.3% in the wavelength band of 450 nm to 500 nm), which was obtained when there was no influence of reflected light, to 8.5% (a maximum value within the predetermined wavelength band of 350 nm to 1100 nm, and in this case, 8.5% in a wavelength band of 1000 nm to 1050 nm).

In particular, a significant deviation from the ideal state is observed in a wavelength region of not shorter than 850 nm but not higher than 1100 nm. In a wavelength region higher than 900 nm, in which a significant deviation from the ideal state is observed, the degree of spectral coincidence does not meet a degree of spectral coincidence of within ±5% (MS class according to JIS), which is required in a high-precision simulated sunlight irradiation apparatus.

In contrast, data of a lower-side-arrangement state in the verification data shown in (B) of FIG. 13, in which lower-side-arrangement state the light absorbing member 18 is provided below the light guide plate 5, was obtained, for comparison, by applying the embodiment of the simulated sunlight irradiation apparatus 101c illustrated in FIG. 12. The data shows a degree of spectral coincidence in the predetermined wavelength band of 350 nm to 1100 nm in a case where a soda glass plate having a thickness of 6 mm was provided as the light absorbing member 18 on a lower side of the light guide plate 5 (on a side opposite to the solar cell B of the light guide plate 5).

This verification result shows that, since light in the infrared region contained in the reflected light from the solar cell B can be effectively reduced, a spectral difference of simulated sunlight is suppressed, so that the deviation from the ideal state is reduced particularly in the wavelength region of not lower than 850 nm but not higher than 1100 nm, as compared with the case in which no light absorbing member 18 is provided. It was thus verified that, by providing the light absorbing member 18 to thereby absorb light in the infrared region contained in the reflected light, a high-precision simulated sunlight irradiation apparatus spectrum having a degree of spectral coincidence within ±5% can be provided.

In contrast, data of an upper-side-arrangement state in the verification data shown in (c) of FIG. 13, in which upper-side-arrangement state the light absorbing member 18 is provided above the light guide plate 5, was obtained, for comparison, by applying the embodiment of the simulated sunlight irradiation apparatus 101a illustrated in FIG. 10. The data shows a degree of spectral coincidence in the predetermined wavelength band of 350 nm to 1100 nm in a case where a soda glass plate having a thickness of 6 mm was provided as the light absorbing member 8 on an upper side of the light guide plate 5 (on a solar cell B side of the light guide plate 5).

This verification result shows that, since light in the infrared region contained in the reflected light from the solar cell B can be reduced, a spectral difference in simulated sunlight is suppressed, so that the deviation from the ideal state is particularly small in the wavelength region of not shorter than 850 nm but not higher than 1100 nm, as compared with the case where no light absorbing member 8 is provided.

As for positional arrangement of the light absorbing members 8 and 18, a value of the degree of spectral coincidence, which indicates the maximum spectral difference, is −4.0% in the case where the light absorbing member 18 is provided on the lower side in (b) of FIG. 13, and is −4.7% in the case where the light absorbing member 8 is provided on the upper side in (c) of FIG. 13. This shows that an even better result is obtained by providing a light absorbing member is provided on the lower side.

Note that the result is obtained for the following reason. In the case where the light absorbing member 8 was provided on the upper side, light that was directly emitted from the light guide plate 5 and then directly applied to the solar cell B also passed through the light absorbing member 8, so that the light absorption effect was relatively reduced.

### Conclusion of Embodiments

As described above, a simulated sunlight irradiation apparatus in accordance with the present embodiments is a simulated sunlight irradiation apparatus including: a light source emitting light; a spectrum adjusting member adjusting a spectrum of the light emitted from the light source; a light guide plate which the light whose spectrum has been adjusted by the spectrum adjusting member enters and in which the light is guided, the light guide plate having an irradiation surface and a counter surface opposite to the irradiation surface; a light extracting member causing the light which has entered the light guide plate to be extracted through the irradiation surface toward an irradiation target; and a light absorbing member absorbing light in a predetermined wavelength region, the light absorbing member being provided on at least one of an irradiation surface side and a counter surface side of the light guide plate.

With the above arrangement, light from the light source is adjusted by the spectrum adjusting member so as to have a desired spectral distribution, and then enters the light guide plate as simulated sunlight. Then, the light which has entered the light guide plate is emitted, by means of the light extracting member, through the irradiation surface of the light guide plate toward the irradiation target.

Note, here, that in a conventional case where a solar cell, which is an irradiation target, is irradiated with simulated sunlight by use of a simulated sunlight irradiation apparatus in order to measure an output characteristic of the solar cell, light (hereinafter referred to as reflected light) reflected from the solar cell among the simulated sunlight is re-applied to the solar cell, so that an error is caused in measured output characteristic of the solar cell.

In view of this, in the above arrangement, the light absorbing member absorbing light in the predetermined wavelength region is provided on at least one of the irradiation surface side and the counter surface side of the light guide plate. As such, by controlling, in accordance with the wavelength region of the reflected light, a wavelength region of light absorbed by the light absorbing member, reflected light can be absorbed by use of the light absorbing member.

Therefore, the above arrangement makes it possible to provide a simulated sunlight irradiation apparatus which suppresses re-application, to an irradiation target, of reflected light from the irradiation target. This makes it possible to reduce a measurement error as described above of an output characteristic of the solar cell.

The simulated sunlight irradiation apparatus in accordance with the present embodiments is preferably arranged such that the light absorbing member absorbs light in an infrared region.

Light that is in the infrared region and contained in reflected light is a particularly significant cause of the measurement error as described above of the output characteristic of the solar cell. As such, in a case, for example, where the solar cell is irradiated with light by use of the simulated sunlight irradiation apparatus, the measurement error of the output characteristic of the solar cell can be effectively reduced by mainly absorbing, by use of the absorbing member, the light that is in the infrared region and contained in reflected light.

The simulated sunlight irradiation apparatus in accordance with the present embodiment is preferably arranged such that the light absorbing member is provided between the irradiation surface of the light guide plate and the irradiation target.

In the above arrangement, the light absorbing member is provided between the irradiation surface of the light guide plate and the irradiation target. Note, here, that part of reflected light from the irradiation target may be reflected from a surface of the light guide plate so as to be re-applied to the irradiation target. Also in this case, providing the light absorbing member between the irradiation surface of the light guide plate and the irradiation target causes the reflected light from the irradiation target to pass through the light absorbing member twice in an optical path from a point where the reflected light is reflected from the surface of the light guide plate to a point where the reflected light is re-applied to the irradiation target. That is, the reflected light from the irradiation target passes through the light absorbing member both in an optical path in which the reflected light travels from the irradiation target to the surface of the light guide plate and in an optical path in which the reflected light travels after being reflected from the surface of the light guide plate until being re-applied to the irradiation target.

Therefore, with the above arrangement, reflected light from the irradiation target can be efficiently absorbed by the light absorbing member.

The simulated sunlight irradiation apparatus in accordance with the present embodiment is preferably arranged such that the light absorbing member is provided on the counter surface side of the light guide plate.

In the above arrangement, the light absorbing member is provided on the counter surface side of the light guide plate. As such, simulated sunlight emitted through the exit surface of the light guide plate toward the irradiation target is directly applied to the irradiation target without passing through the light absorbing member.

Accordingly, the arrangement allows a light absorptance of the light absorbing member to be set to a high value, so that reflected light having passed through the light guide plate after being reflected by the solar sell can be absorbed by the light absorbing member almost completely.

It is preferable that the simulated sunlight irradiation apparatus in accordance with the present embodiment further include a reflecting member which is provided so as to face the counter surface of the light guide plate and reflects, toward the irradiation surface of the light guide plate, light emitted from the counter surface.

In the above arrangement, the reflecting member which reflects, toward the irradiation surface of the light guide plate, light emitted from the counter surface is provided on the counter surface side of the light guide plate. This allows more efficient use of light in the simulated sunlight irradiation apparatus.

The simulated sunlight irradiation apparatus in accordance with the present embodiment is preferably arranged such that the light absorbing member is provided between the counter surface of the light guide plate and the reflecting member.

In the above arrangement, the light absorbing member is arranged between the counter surface of the light guide plate and the reflecting member. This makes it possible to absorb, by use of the light absorbing member, (i) reflected light that has passed through the light guide plate and (ii) reflected light that has been reflected by the reflecting member after passing through the light guide plate.

The simulated sunlight irradiation apparatus in accordance with the present embodiment is preferably arranged such that the light absorbing member is integrally formed with the reflecting member.

In the above arrangement, the light absorbing member and the reflecting member are integrally formed. This makes it possible to reduce a width of the simulated sunlight irradiation apparatus along a height direction thereof, and thus reduce a size of the simulated sunlight irradiation apparatus.

The simulated sunlight irradiation apparatus in accordance with the present embodiment is preferably arranged such that the light absorbing member is provided with antireflection means for preventing reflection of light.

In the above arrangement, the light absorbing member is provided with the antireflection means such as antireflection film. This reduces a reflectance on a surface of the light absorbing member. This makes it possible to suppress surface reflection of the light absorbing member.

Accordingly, the above arrangement increases light that passes through the light absorbing member. This allows reflected light to be absorbed by the light absorbing member more efficiently.

The above arrangement also makes it possible to reduce light reflected on a surface (surface on the irradiation target side) of the light absorbing member among the reflected light from the irradiation target, and thus suppress re-application of the reflected light to the irradiation target.

The simulated sunlight irradiation apparatus in accordance with the present embodiment is preferably arranged such that the light absorbing member has been subjected to a diffusion treatment for diffusing light.

In the above arrangement, the light absorbing member has been subjected to the diffusion treatment for diffusing light. This allows reflected light to be reflected from a surface of the light absorbing member in various directions, so that reflected light that is obliquely applied to the irradiation target is relatively increased.

Therefore, the above arrangement allows a reduction in an influence of reflected light as compared with a case in which reflected light is perpendicularly applied to the irradiation target.

Further, with the above arrangement, light diffused on the surface of the light absorbing member enters the light absorbing member. Accordingly, an optical path in which the reflected light travels inside the light absorbing member is relatively increased. This allows the reflected light to be absorbed more efficiently.

The simulated sunlight irradiation apparatus in accordance with the present embodiment is preferably arranged such that the light source includes a first light source emitting first light and a second light source emitting second light having a spectral distribution different from that of the first light; the spectrum adjusting member includes a first spectrum adjusting member adjusting a spectrum of the first light and a second spectrum adjusting member adjusting a spectrum of the second light; and the simulated sunlight irradiation apparatus further includes a wavelength selecting member which the first light whose spectrum has been adjusted by the first spectrum adjusting member and the second light whose spectrum has been adjusted by the second spectrum adjusting member enter, the wavelength selecting member (i) selecting light from the first light and the second light each of which has entered the wavelength selecting member, (ii) mixing the light thus selected, and (iii) emitting the light thus mixed to the light guide plate.

In the above arrangement, simulated sunlight is generated by mixing light selected from the first light whose spectrum has been adjusted by the adjusting member and light selected from the second light whose spectrum has been adjusted by the second spectrum adjusting member.

Accordingly, the above arrangement allows generated light to have a spectrum with an improved precision, so that simulated sunlight having a spectrum close to that of the standard sunlight can be emitted.

The simulated sunlight irradiation apparatus in accordance with the present embodiment is preferably arranged such that: the first light has a wavelength longer than that of the second light; the wavelength selecting member (i) transmits and emits, to the light guide plate, light having a wavelength longer than a predetermined boundary wavelength among the first light whose spectrum has been adjusted by the first spectrum adjusting member and (ii) reflects and emits, to the light guide plate, light having a wavelength shorter than the predetermined boundary wavelength among the second light whose spectrum has been adjusted by the second spectrum adjusting member; and the light absorbing member absorbs light having a wavelength longer than the boundary wavelength.

The above arrangement makes it possible to provide a suitable wavelength selecting member that (i) selects light having a desired wavelength region from the first light whose spectrum has been adjusted by the first spectrum adjusting member and from the second light whose spectrum has been adjusted by the second spectrum adjusting member and (ii) mixes the light thus selected.

Further, since the light absorbing member absorbs light having a wavelength longer than the boundary wavelength, it is possible to effectively absorb, for example, long-wavelength light (e.g., light in the infrared region) contained in the reflected light.

A simulated sunlight irradiation apparatus in accordance with the present embodiment is a simulated sunlight irradiation apparatus which irradiates a solar cell with simulated sunlight in order to measure an output characteristic of the solar cell, including: a light source emitting light; a spectrum adjusting member adjusting a spectrum of the light emitted from the light source; a light guide plate which the light whose spectrum has been adjusted by the spectrum adjusting member enters and in which the light is guided, the light guide plate having an irradiation surface and a counter surface opposite to the irradiation surface; a light extracting member causing the light which has entered the light guide plate to be extracted through the irradiation surface toward an irradiation target; and a light absorbing member capable of absorbing light in a predetermined wavelength region and contained in reflected light which is simulated sunlight reflected from the solar cell, the light absorbing member being provided on at least one of an irradiation surface side and a counter surface side of the light guide plate.

The above arrangement makes it possible to provide a simulated sunlight irradiation apparatus which suppresses re-application, to a solar cell, of light reflected from the solar cell. Accordingly, a measurement error as described above of an output characteristic of the solar cell can be reduced.

The present invention is not limited to the above-described embodiments but allows various modifications within the scope of the claims. Any embodiment derived from an appropriate combination of the technical means disclosed in the different embodiments will also be included in the technical scope of the present invention.

[Additional Matters]

Note that a simulated sunlight irradiation apparatus of the present invention can also be expressed as follows. That is, a simulated sunlight irradiation apparatus of the present invention is a simulated sunlight irradiation apparatus including: a light source; a light guide member giving a directivity to light emitted from the light source; a spectrum adjusting member for adjusting a spectrum of light having exited the light guide member; and a light guide plate which light having exited the spectrum adjusting member enters, wherein a light extracting structure is formed as part of the light guide plate, and a light absorbing member is provided in a position higher than or lower than the light guide plate.

A simulated sunlight irradiation apparatus of the present invention is arranged such that the light absorbing member absorbs infrared light more than light in other wavelength region.

A simulated sunlight irradiation apparatus of the present invention is arranged such that the light absorbing member is provided in a position higher than the light guide plate.

A simulated sunlight irradiation apparatus of the present invention is arranged such that (i) a reflecting member which reflects, toward the light guide plate, light emitted downward from the light guide plate, is provided on a lower side of the light guide plate and (ii) the light absorbing member is provided in a position closer to the light guide plate than the reflecting plate member is.

A simulated sunlight irradiation apparatus of the present invention is arranged such that the light absorbing member is integrally formed with the light guide plate.

A simulated sunlight irradiation apparatus of the present invention is arranged such that the light absorbing member is integrally formed with the reflecting plate.

A simulated sunlight irradiation apparatus of the present invention is arranged such that an antireflection film is formed on a surface of the light absorbing member.

A simulated sunlight irradiation apparatus of the present invention is arranged such that a surface of the light absorbing member is subjected to a diffusion treatment.

A simulated sunlight irradiation apparatus of the present invention is arranged such that (i) the light source includes a first light source and a second light source which are different from each other in spectrum, (ii) (a) a first light guide member giving a directivity to light emitted from the first light source, (b) a second light guide member giving a directivity to light emitted from the second light source, (c) a first spectrum adjusting member for the first light source, (d) a second spectrum adjusting member for the second light source, (e) a wavelength selecting member which transmits light having a wavelength longer than a predetermined boundary wavelength among light that has exited the first spectrum adjusting member and which reflects light having a wavelength shorter than the predetermined boundary wavelength among light that has exited the second spectrum adjusting member are provided at an incident end of the light guide plate, and (iii) the light absorbing member absorbs light having a wavelength longer than the boundary wavelength more than light having a wavelength shorter than the boundary wavelength.

A simulated sunlight irradiation apparatus of the present invention is a simulated sunlight irradiation apparatus which irradiates a solar cell panel or a solar cell module with light in order to evaluate a characteristic of the solar cell panel or the solar cell module, including: a light source; a light guide member giving a directivity to light emitted from the light source; a spectrum adjusting member for adjusting a spectrum of light having exited the light guide member; and a light guide plate which irradiates the solar cell panel or the solar cell module with light having exited the spectrum adjusting member, the light serving as measurement light, wherein, in order to suppress a phenomenon in which reflected light form the solar cell panel or the solar cell module is reflected by other member again so as to be mixed with the measurement light and then reenter the solar cell panel or the solar cell module, a light absorbing member for absorbing part of the reflected light is provided in a position higher than or lower than the light guide plate.

### INDUSTRIAL APPLICABILITY

The present invention is suitably applicable to tests, measurements, and experiments of solar cells. The present invention is also applicable to color degradation and reaction-to-light tests of cosmetics, paints, adhesives, and other various materials. In addition, the present invention is applicable to tests and experiments of photocatalysts, and other various experiments/tests that require natural light.

### REFERENCE SIGNS LIST

1 halogen lamp (first light source)
4 optical filter (spectrum adjusting member, first spectrum adjusting member)
6 light extracting section (light extracting member)
7 reflecting plate (reflecting member)
8 light absorbing member
11 xenon lamp (light source, second light source)
14 optical filter (second spectrum adjusting member)
15 wavelength selecting filter (wavelength selecting member)
18 light absorbing member
100a simulated sunlight irradiation apparatus
100b simulated sunlight irradiation apparatus
100c simulated sunlight irradiation apparatus
100d simulated sunlight irradiation apparatus
100e simulated sunlight irradiation apparatus
101a simulated sunlight irradiation apparatus
101b simulated sunlight irradiation apparatus
101c simulated sunlight irradiation apparatus
B solar cell (irradiation target)

1. A simulated sunlight irradiation apparatus, comprising:
a light source emitting light;
a spectrum adjusting member adjusting a spectrum of the light emitted from the light source;
a light guide plate which the light whose spectrum has been adjusted by the spectrum adjusting member enters and in which the light is guided, the light guide plate having an irradiation surface and a counter surface opposite to the irradiation surface;
a light extracting member causing the light which has entered the light guide plate to be extracted through the irradiation surface toward an irradiation target; and
a light absorbing member absorbing light in a predetermined wavelength region, the light absorbing member being provided on at least one of an irradiation surface side and a counter surface side of the light guide plate.

2. The simulated sunlight irradiation apparatus as set forth in claim 1, wherein:
the light absorbing member absorbs light in an infrared region.

3. The simulated sunlight irradiation apparatus as set forth in claim 1, wherein:
the light absorbing member is provided between the irradiation surface of the light guide plate and the irradiation target.

4. The simulated sunlight irradiation apparatus as set forth in claim 1, wherein:
the light absorbing member is provided on the counter surface side of the light guide plate.

5. A simulated sunlight irradiation apparatus as set forth in claim 1, further comprising a reflecting member which is provided so as to face the counter surface of the light guide plate and reflects, toward the irradiation surface of the light guide plate, light emitted from the counter surface.

6. The simulated sunlight irradiation apparatus as set forth in claim 5, wherein:
the light absorbing member is provided between the counter surface of the light guide plate and the reflecting member.

7. The simulated sunlight irradiation apparatus as set forth in claim 6, wherein:
the light absorbing member is integrally formed with the reflecting member.

8. The simulated sunlight irradiation apparatus as set forth in claim 1, wherein:
the light absorbing member provided with antireflection means for preventing reflection of light.

9. The simulated sunlight irradiation apparatus as set forth in claim 1, wherein:
the light absorbing member has been subjected to a diffusion treatment for diffusing light.

10. The simulated sunlight irradiation apparatus as set forth in claim 1, wherein:
the light source includes a first light source emitting first light and a second light source emitting second light having a spectral distribution different from that of the first light;
the spectrum adjusting member includes a first spectrum adjusting member adjusting a spectrum of the first light and a second spectrum adjusting member adjusting a spectrum of the second light; and
the simulated sunlight irradiation apparatus further comprises a wavelength selecting member which the first light whose spectrum has been adjusted by the first spectrum adjusting member and the second light whose spectrum has been adjusted by the second spectrum adjusting member enter, the wavelength selecting member (i) selecting light from the first light and the second light each of which has entered the wavelength selecting member, (ii) mixing the light thus selected, and (iii) emitting the light thus mixed to the light guide plate.

11. The simulated sunlight irradiation apparatus as set forth in claim 10, wherein:
the first light has a wavelength longer than that of the second light;
the wavelength selecting member (i) transmits and emits, to the light guide plate, light having a wavelength longer than a predetermined boundary wavelength among the first light whose spectrum has been adjusted by the first spectrum adjusting member and (ii) reflects and emits, to the light guide plate, light having a wavelength shorter than the predetermined boundary wavelength among the second light whose spectrum has been adjusted by the second spectrum adjusting member; and
the light absorbing member absorbs light having a wavelength longer than the boundary wavelength.

12. A simulated sunlight irradiation apparatus which irradiates a solar cell with simulated sunlight in order to measure an output characteristic of the solar cell, comprising:
a light source emitting light;
a spectrum adjusting member adjusting a spectrum of the light emitted from the light source;
a light guide plate which the light whose spectrum has been adjusted by the spectrum adjusting member enters and in which the light is guided, the light guide plate having an irradiation surface and a counter surface opposite to the irradiation surface;
a light extracting member causing the light which has entered the light guide plate to be extracted through the irradiation surface toward an irradiation target; and
a light absorbing member capable of absorbing light that is in a predetermined wavelength region and contained in reflected light which is simulated sunlight reflected from the solar cell, the light absorbing member being provided on at least one of an irradiation surface side and a counter surface side of the light guide plate.
